(19) United States
(12) Patent Application Publication
(10) Pub. No.: US 2026/0351321 A1
(43) Pub. Date: Nov. 5, 2026

(54) INDEPENDENT DUMMY JOINT BIAS CONTROL FOR SUB-BLOCK MODE

(71) Applicant: Sandisk Technologies, Inc., Milpitas, CA (US)

(72) Inventor: Jiacen Guo, Cupertino, CA (US)

(21) Appl. No.: 19/196,826

(22) Filed: May 2, 2025

(51) Int. Cl. G11C 16/34; G11C 11/56; G11C 16/04; G11C 16/10

(52) U.S. Cl. CPC G11C 16/3427; G11C 11/5628; G11C 11/5671; G11C 16/0483; G11C 16/10

(57) ABSTRACT

A memory apparatus includes memory cells each connected to one of a plurality of word lines and disposed in memory holes extending vertically through a stack of the plurality of word lines. The memory cells are configured to retain a threshold voltage corresponding to data states. The memory cells form a block including a first sub-block vertically below a second sub-block to define an interface region therebetween. The plurality of word lines includes a plurality of dummy word lines being disposed adjacent the interface region. A control means is configured to program the memory cells of the first sub-block and the second sub-block independently of one another in a program operation. The control means is also configured to apply different bias voltages to ones of the plurality of dummy word lines depending on the one of the first sub-block and the second sub-block being programmed in the program operation.

### FIELD

This application relates to non-volatile memory apparatuses and the operation of non-volatile memory apparatuses.

### BACKGROUND

This section provides background information related to the technology associated with the present disclosure and, as such, is not necessarily prior art.

Semiconductor memory devices have become more popular for use in various electronic devices. For example, non-volatile semiconductor memory is used in cellular telephones, digital cameras, personal digital assistants, mobile computing devices, non-mobile computing devices and other devices.

A charge-trapping material can be used in such memory devices to store a charge which represents a data state. The charge-trapping material can be arranged vertically in a three-dimensional (3D) stacked memory structure, or horizontally in a two-dimensional (2D) memory structure. One example of a 3D memory structure is the Bit Cost Scalable (BiCS) architecture which comprises a stack of alternating conductive and dielectric layers.

Each memory cell includes the charge-trapping material and may be programmed to store an amount of charge which represents a data state. The memory cells may be arranged in strings or memory holes, for instance, where select gate transistors are provided at the ends of the string to selectively connect a channel of the string to a source line or bit line. However, various challenges are presented in operating such memory devices.

### SUMMARY

This section provides a general summary of the present disclosure and is not a comprehensive disclosure of its full scope or all of its features and advantages.

An object of the present disclosure is to provide a memory apparatus and a method of operation of the memory apparatus that address and overcome shortcomings described herein.

Accordingly, it is an aspect of the present disclosure to provide a memory apparatus including memory cells each connected to one of a plurality of word lines. The memory cells are disposed in memory holes extending vertically through a stack of the plurality of word lines. The memory cells are configured to retain a threshold voltage corresponding to one of a plurality of data states. The memory cells form a block including a first sub-block vertically below a second sub-block to define an interface region therebetween. The plurality of word lines includes a plurality of dummy word lines being disposed adjacent the interface region. The memory apparatus also includes a control means configured to program the memory cells of the first sub-block and the second sub-block independently of one another in a program operation. The control means is also configured to apply different bias voltages to ones of the plurality of dummy word lines depending on the one of the first sub-block and the second sub-block being programmed in the program operation.

According to another aspect of the disclosure, a controller in communication with a memory apparatus including memory cells each connected to one of a plurality of word lines is provided. The memory cells are disposed in memory holes extending vertically through a stack of the plurality of word lines. The memory cells are configured to retain a threshold voltage corresponding to one of a plurality of data states. The memory cells form a block including a first sub-block vertically below a second sub-block to define an interface region therebetween. The plurality of word lines includes a plurality of dummy word lines being disposed adjacent the interface region. The controller is configured to instruct the memory apparatus to instruct the memory apparatus to program the memory cells of the first sub-block and the second sub-block independently of one another in a program operation. The controller is also configured to instruct the memory apparatus to apply different bias voltages to ones of the plurality of dummy word lines depending on the one of the first sub-block and the second sub-block being programmed in the program operation.

According to an additional aspect of the disclosure, a method of operating a memory apparatus is provided. The memory apparatus includes memory cells each connected to one of a plurality of word lines. The memory cells are disposed in memory holes extending vertically through a stack of the plurality of word lines. The memory cells are configured to retain a threshold voltage corresponding to one of a plurality of data states. The memory cells form a block including a first sub-block vertically below a second sub-block to define an interface region therebetween. The plurality of word lines includes a plurality of dummy word lines being disposed adjacent the interface region. The method includes the step of programming the memory cells of the first sub-block and the second sub-block independently of one another in a program operation. The method also includes the step of applying different bias voltages to ones of the plurality of dummy word lines depending on the one of the first sub-block and the second sub-block being programmed in the program operation.

Further areas of applicability will become apparent from the description provided herein. The description and specific examples in this summary are intended for purposes of illustration only and are not intended to limit the scope of the present disclosure.

### BRIEF DESCRIPTION OF THE DRAWINGS

For a detailed description of example embodiments, reference will now be made to the accompanying drawings in which:

FIG. 1 is a block diagram depicting one embodiment of a storage system according to aspects of the disclosure;

FIG. 2A is a block diagram of one embodiment of a memory die according to aspects of the disclosure;

FIG. 2B is a block diagram of one embodiment of an integrated memory assembly according to aspects of the disclosure;

FIGS. 2C and 2D depict different embodiments of integrated memory assemblies according to aspects of the disclosure;

FIG. 3 is a perspective view of a portion of one embodiment of a monolithic three dimensional memory structure according to aspects of the disclosure;

FIG. 4A is a block diagram of one embodiment of a memory structure having two planes according to aspects of the disclosure;

FIG. 4B depicts a top view of a portion of one embodiment of a block of memory cells according to aspects of the disclosure;

FIG. 4C depicts a cross sectional view of a portion of one embodiment of a block of memory cells according to aspects of the disclosure;

FIG. 4D is a cross sectional view of one embodiment of a vertical column of memory cells according to aspects of the disclosure;

FIG. 4E is a schematic of a plurality of NAND strings showing multiple sub-blocks according to aspects of the disclosure;

FIG. 4F depicts a top view of a portion of one embodiment of a block of memory cells according to aspects of the disclosure;

FIG. 4G depicts a top view of a portion of one embodiment of a block of memory cells according to aspects of the disclosure;

FIG. 4H is a schematic of one embodiment of a plurality of NAND strings showing multiple sub-blocks according to aspects of the disclosure;

FIG. 5 depicts threshold voltage distributions according to aspects of the disclosure;

FIG. 6 is a table describing one example of an assignment of data values to data states according to aspects of the disclosure;

FIG. 7 is a flow chart describing one embodiment of a process for programming non-volatile memory according to aspects of the disclosure;

FIGS. 8A and 8B depict examples of word line programming orders for a two sub-block, upper sub-block/lower sub-block embodiment according to aspects of the disclosure;

FIG. 9 shows a block of memory cells divided into a first sub-block SB0 vertically disposed below a second sub-block SB1 along with a corresponding circuit diagram of one memory hole of the block with memory cells connected to dummy word lines at the joint or interface region between the sub-blocks and illustrates a programming order of each sub-block as well as the voltages to word lines of each sub-block applied during programming according to aspects of the disclosure;

FIG. 10 shows a threshold voltage distribution for a non-ideal threshold voltage of the memory cells connected to the dummy word lines along with an associated plot of the threshold voltage distributions of the memory cells connected to data word lines of the sub-blocks according to aspects of the disclosure;

FIG. 11 shows a threshold voltage distribution for a tuned threshold voltage of the memory cells connected to the dummy word lines along with an associated plot of the threshold voltage distributions of the memory cells connected to data word lines of the sub-blocks according to aspects of the disclosure;

FIG. 12 shows another block of memory cells divided into a first sub-block vertically disposed below a second sub-block along with a corresponding circuit diagram of one memory hole of the block with memory cells connected to dummy word lines at the joint or interface region between the sub-blocks and illustrates voltages applied to a bit line connected to each of the memory holes of the block during programming along with a voltage or bias applied to the dummy word lines during programming of the first sub-block according to aspects of the disclosure;

FIG. 13 shows plots of an erase upper tail, threshold voltage window, and threshold voltage distribution width versus physical word line for memory cells of blocks cycled at high temperature according to aspects of the disclosure;

FIG. 14 shows another block of memory cells divided into a first sub-block vertically disposed below a second sub-block along with a corresponding circuit diagram of one memory hole of the block with memory cells connected to dummy word lines at the joint or interface region between the sub-blocks and illustrates voltages applied to a bit line connected to each of the memory holes of the block during programming along with a voltage or bias applied to the dummy word lines during programming of the second sub-block according to aspects of the disclosure;

FIG. 15 is a plot of an erase upper tail versus physical word line for the non-ideal threshold voltage of the memory cells connected to the dummy word lines and the tuned threshold voltage of the memory cells connected to the dummy word lines at a high temperature for the second sub-block according to aspects of the disclosure;

FIG. 16 shows a threshold voltage distribution for the non-ideal threshold voltage of the memory cells connected to the dummy word lines and the voltage applied to the dummy word lines during programming of the second sub-block resulting in corresponding erase upper tail of FIG. 15 according to aspects of the disclosure;

FIG. 17 shows a threshold voltage distribution for the tuned threshold voltage of the memory cells connected to the dummy word lines and the voltage applied to the dummy word lines during programming of the second sub-block resulting in corresponding erase upper tail of FIG. 15 according to aspects of the disclosure;

FIG. 18 shows another block of memory cells divided into a first sub-block SB0 vertically disposed below a second sub-block along with a corresponding circuit diagram of one memory hole of the block with memory cells connected to dummy word lines at the joint or interface region between the sub-blocks and illustrates voltages applied to a bit line connected to each of the memory holes of the block during programming along with a different voltage or bias applied to the dummy word lines depending on the one of the first sub-block and the second sub-block being programmed in the program operation according to aspects of the disclosure; and

FIG. 19 illustrates steps of a method of operating a memory apparatus according to aspects of the disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following description, details are set forth to provide an understanding of the present disclosure. In some instances, certain circuits, structures and techniques have not been described or shown in detail in order not to obscure the disclosure.

In general, the present disclosure relates to non-volatile memory apparatuses of the type well-suited for use in many applications. The non-volatile memory apparatus and associated methods of forming of this disclosure will be described in conjunction with one or more example embodiments. However, the specific example embodiments disclosed are merely provided to describe the inventive concepts, features, advantages and objectives with sufficient clarity to permit those skilled in this art to understand and practice the disclosure. Specifically, the example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

Various terms are used to refer to particular system components. Different companies may refer to a component by different names—this document does not intend to distinguish between components that differ in name but not function. In the following discussion and in the claims, the terms “including” and “comprising” are used in an open-ended fashion, and thus should be interpreted to mean “including, but not limited to . . .” Also, the term “couple” or “couples” is intended to mean either an indirect or direct connection. Thus, if a first device couples to a second device, that connection may be through a direct connection or through an indirect connection via other devices and connections.

Additionally, when a layer or element is referred to as being “on” another layer or substrate, in can be directly on the other layer of substrate, or intervening layers may also be present. Further, it will be understood that when a layer is referred to as being “under” another layer, it can be directly under, and one or more intervening layers may also be present. Furthermore, when a layer is referred to as “between” two layers, it can be the only layer between the two layers, or one or more intervening layers may also be present.

For purposes of this document, reference in the specification to “an embodiment,” “one embodiment,” “some embodiments,” or “another embodiment” may be used to describe different embodiments or the same embodiment.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

As described, non-volatile memory systems are a type of memory that retains stored information without requiring an external power source. Non-volatile memory is widely used in various electronic devices and in stand-alone memory devices. For example, non-volatile memory can be found in laptops, digital audio player, digital cameras, smart phones, video games, scientific instruments, industrial robots, medical electronics, solid-state drives, USB drives, memory cards, and the like. Non-volatile memory can be electronically programmed/reprogrammed and erased.

Examples of non-volatile memory systems include flash memory, such as NAND flash or NOR flash. NAND flash memory structures typically arrange multiple memory cell transistors (e.g., floating-gate transistors or charge trap transistors) in series with and between two select gates (e.g., a drain-side select gate and a source-side select gate). The memory cell transistors in series and the select gates may be referred to as a NAND string. NAND flash memory may be scaled in order to reduce cost per bit.

A programming operation for a set of memory cells of a memory device typically involves applying a series of program voltages to the memory cells after the memory cells are provided in an erased state. Each program voltage is provided in a program loop, also referred to as a program-verify iteration. For example, the program voltage may be applied to a word line which is connected to control gates of the memory cells. In one approach, incremental step pulse programming is performed, where the program voltage is increased by a step size in each program loop. Verify operations may be performed after each program voltage to determine whether the memory cells have completed programming. When programming is completed for a memory cell, it can be locked out from further programming while programming continues for other memory cells in subsequent program loops.

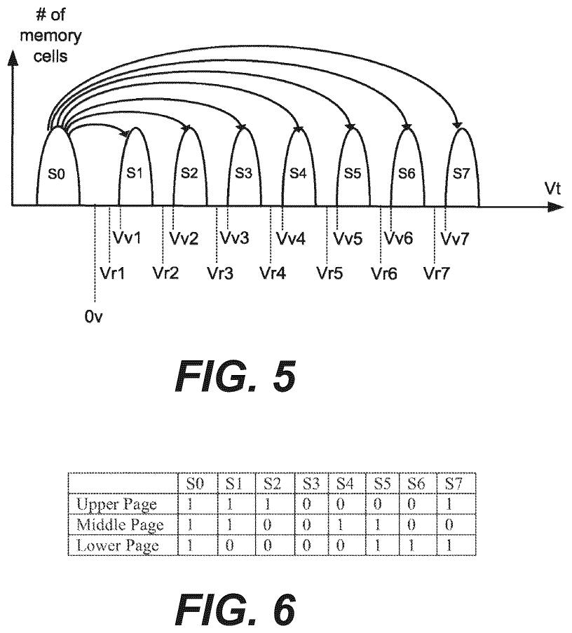

Each memory cell may be associated with a data state according to write data in a program command. Based on its data state, a memory cell will either remain in the erased state or be programmed to a data state (a programmed data state) different from the erased state. For example, in a one-bit per cell memory device (single-level cell (SLC)), there are two data states including the erased state and one higher data state. In a two-bit per cell memory device (multi-level cell (MLC)), there are four data states including the erased state and three higher data states referred to as the A, B and C data states. In a three-bit per cell memory device (triple-level cell (TLC)), there are eight data states including the erased or S0 state and seven higher data states referred to as the A, B, C, D, E, F and G data states or S1, S2, S3, S4, S5, S6, S7 data states (see FIG. 5). In a four-bit per cell memory device (quad-level cell (QLC)), there are sixteen data states including the erased state and fifteen higher data states referred to as the Er, S1, S2, S3, S4, S5, S6, S7, S8, S9, S10, S11, S12, S13, S14, S15 data states. Each memory cell may store a data state (e.g., a binary value) and is programmed to a threshold voltage state corresponding to the data state. Each state represents a different value and is assigned a voltage window including a range of possible threshold voltages.

In a 3D NAND structure, a block of the memory cells may be formed into tiers, separated by a joint region and operable as sub-blocks. When operating a memory apparatus utilizing sub-blocks (i.e., in a sub-block mode (SBM)), the threshold voltage of memory cells connected to dummy word lines adjacent the joint region being too low may adversely affect programming of the other memory cells of the sub-blocks.

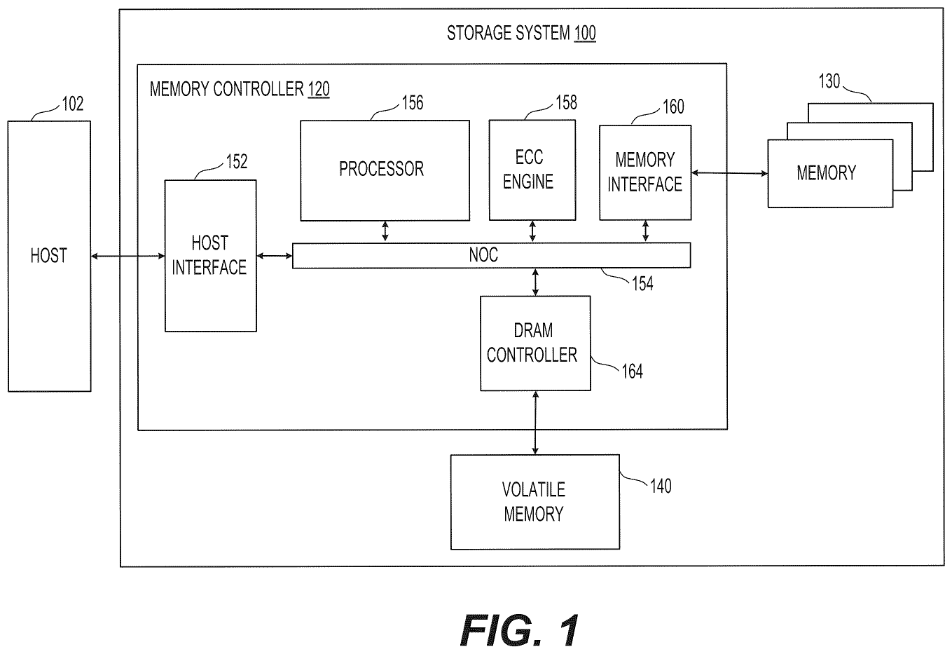

FIG. 1 is a block diagram of one embodiment of a storage system 100 that implements the proposed technology described herein. In one embodiment, storage system 100 is a solid state drive (“SSD”). Storage system 100 can also be a memory card, USB drive or other type of storage system. The proposed technology is not limited to any one type of memory system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 connected to non-volatile memory 130 and local high speed volatile memory 140 (e.g., DRAM). Local high speed volatile memory 140 is used by memory controller 120 to perform certain functions. For example, local high speed volatile memory 140 stores logical to physical address translation tables (“L2P tables”).

Memory controller 120 comprises a host interface 152 that is connected to and in communication with host 102. In one embodiment, host interface 152 implements a NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, and DRAM controller 164. DRAM controller 164 is used to operate and communicate with local high speed volatile memory 140 (e.g., DRAM). In other embodiments, local high speed volatile memory 140 can be SRAM or another type of volatile memory.

ECC engine 158 performs error correction services. For example, ECC engine 158 performs data encoding and decoding, as per the implemented ECC technique. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory dies. One example implementation is to maintain tables (i.e., the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in a memory die 130 and a subset of the L2P tables are cached (L2P cache) in the local high speed volatile memory 140.

Memory interface 160 communicates with non-volatile memory 130. In one embodiment, memory interface provides a Toggle Mode interface. Other interfaces can also be used. In some example implementations, memory interface 160 (or another portion of controller 120) implements a scheduler and buffer for transmitting data to and receiving data from one or more memory die.

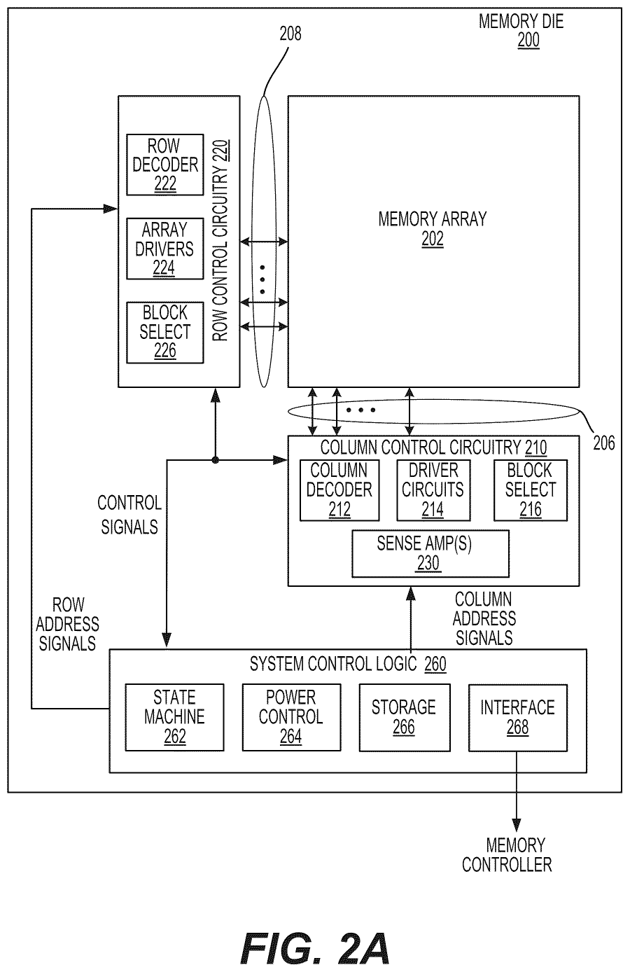

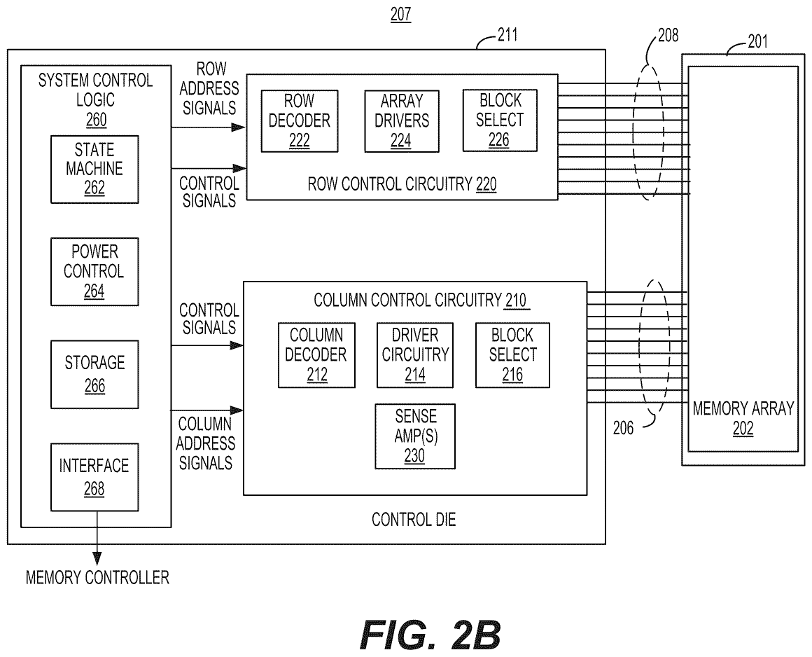

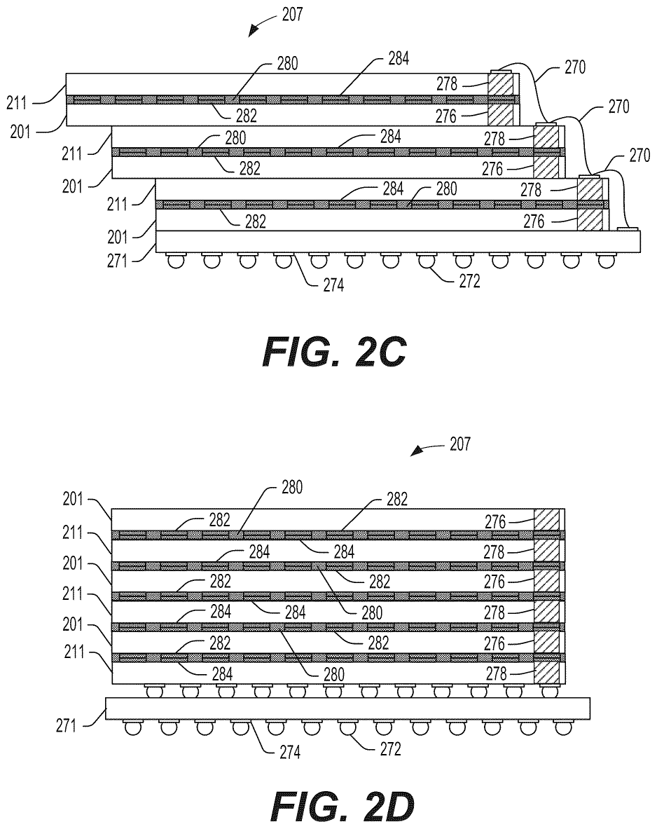

In one embodiment, non-volatile memory 130 comprises one or more memory die. FIG. 2A is a functional block diagram of one embodiment of a memory die 200 that comprises non-volatile memory 130. Each of the one or more memory die of non-volatile memory 130 can be implemented as memory die 200 of FIG. 2A. The components depicted in FIG. 2A are electrical circuits. Memory die 200 includes a memory array 202 that can comprises non-volatile memory cells, as described in more detail below. The array terminal lines of memory array 202 include the various layer(s) of word lines organized as rows, and the various layer(s) of bit lines organized as columns. However, other orientations can also be implemented. Memory die 200 includes row control circuitry 220, whose outputs 208 are connected to respective word lines of the memory array 202. Row control circuitry 220 receives a group of M row address signals and one or more various control signals from System Control Logic circuit 206, and typically may include such circuits as row decoders 222, array terminal drivers 224, and block select circuitry 226 for both reading and writing (programming) operations. Row control circuitry 220 may also include read/write circuitry. Memory die 200 also includes column control circuitry 210 including sense amplifier(s) 230 whose input/outputs 206 are connected to respective bit lines of the memory array 202. Although only single block is shown for array 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuitry 216, as well as read/write circuitry, and I/O multiplexers.

System control logic 260 receives data and commands from memory controller 120 and provides output data and status to the host. In some embodiments, the system control logic 260 (which comprises one or more electrical circuits) include state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 262 can also include a power control module 264 that controls the power and voltages supplied to the rows and columns of the memory structure 202 during memory operations and may include charge pumps and regulator circuit for creating regulating voltages. System control logic 262 includes storage 266 (e.g., RAM, registers, latches, etc.), which may be used to store parameters for operating the memory array 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the non-volatile memory 130 of storage system 100. The integrated memory assembly 207 includes two types of semiconductor die (or more succinctly, “die”). Memory die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory die 201. In some embodiments, the memory die 201 and the control die 211 are bonded together.

FIG. 2B shows an example of the peripheral circuitry, including control circuits, formed in a peripheral circuit or control die 311 coupled to memory structure 202 formed in memory die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory die 201. In some embodiments, some of the circuitry in the system control logic 260 is located on the on the memory die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate controller 120 may also be used to fabricate system control logic 260, row control circuitry 220, and column control circuitry 210). Thus, while moving such circuits from a die such as memory 2 die 201 may reduce the number of steps needed to fabricate such a die, adding such circuits to a die such as control die 311 may not require many additional process steps. The control die 211 could also be referred to as a CMOS die, due to the use of CMOS technology to implement some or all of control circuitry 260, 210, 220.

FIG. 2B shows column control circuitry 210 including sense amplifier(s) 230 on the control die 211 coupled to memory structure 202 on the memory die 201 through electrical paths 206. For example, electrical paths 206 may provide electrical connection between column decoder 212, driver circuitry 214, and block select 216 and bit lines of memory structure 202. Electrical paths may extend from column control circuitry 210 in control die 211 through pads on control die 211 that are bonded to corresponding pads of the memory die 201, which are connected to bit lines of memory structure 202. Each bit line of memory structure 202 may have a corresponding electrical path in electrical paths 306, including a pair of bond pads, which connects to column control circuitry 210. Similarly, row control circuitry 220, including row decoder 222, array drivers 224, and block select 226 are coupled to memory structure 202 through electrical paths 208. Each of electrical path 208 may correspond to a word line, dummy word line, or select gate line. Additional electrical paths may also be provided between control die 211 and memory die 201.

For purposes of this document, the phrases “a control circuit” or “one or more control circuits” can include any one of or any combination of memory controller 120, state machine 262, all or a portion of system control logic 260, all or a portion of row control circuitry 220, all or a portion of column control circuitry 210, a microcontroller, a microprocessor, and/or other similar functioned circuits. The one or more control circuits can include hardware only or a combination of hardware and software (including firmware). For example, a controller programmed by firmware to perform the functions described herein is one example of a control circuit. A control circuit can include a processor, FGA, ASIC, integrated circuit, or other type of circuit.

In some embodiments, there is more than one control die 211 and more than one memory die 201 in an integrated memory assembly 207. In some embodiments, the integrated memory assembly 207 includes a stack of multiple control die 211 and multiple memory die 201. FIG. 2C depicts a side view of an embodiment of an integrated memory assembly 207 stacked on a substrate 271 (e.g., a stack comprising control dies 211 and memory dies 201). The integrated memory assembly 207 has three control dies 211 and three memory dies 201. In some embodiments, there are more than three memory dies 201 and more than three control die 211.

Each control die 211 is affixed (e.g., bonded) to at least one of the memory dies 201. Some of the bond pads 282/284 are depicted. There may be many more bond pads. A space between two dies 201, 211 that are bonded together is filled with a solid layer 280, which may be formed from epoxy or other resin or polymer. This solid layer 280 protects the electrical connections between the dies 201, 211, and further secures the dies together. Various materials may be used as solid layer 280, but in embodiments, it may be Hysol epoxy resin from Henkel Corp., having offices in California, USA.

The integrated memory assembly 207 may for example be stacked with a stepped offset, leaving the bond pads at each level uncovered and accessible from above. Wire bonds 270 connected to the bond pads connect the control die 211 to the substrate 271. A number of such wire bonds may be formed across the width of each control die 211 (i.e., into the page of FIG. 2C).

A memory die through silicon via (TSV) 276 may be used to route signals through a memory die 201. A control die through silicon via (TSV) 278 may be used to route signals through a control die 211. The TSVs 276, 278 may be formed before, during or after formation of the integrated circuits in the semiconductor dies 201, 211. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package. The solder balls 272 may form a part of the interface between integrated memory assembly 207 and memory controller 120.

FIG. 2D depicts a side view of another embodiment of an integrated memory assembly 207 stacked on a substrate 271. The integrated memory assembly 206 of FIG. 2D has three control die 211 and three memory die 201. In some embodiments, there are many more than three memory dies 201 and many more than three control dies 211. In this example, each control die 211 is bonded to at least one memory die 201. Optionally, a control die 211 may be bonded to two or more memory die 201.

Some of the bond pads 282, 284 are depicted. There may be many more bond pads. A space between two dies 201, 211 that are bonded together is filled with a solid layer 280, which may be formed from epoxy or other resin or polymer. In contrast to the example in FIG. 2C, the integrated memory assembly 207 in FIG. 2D does not have a stepped offset. A memory die through silicon via (TSV) 276 may be used to route signals through a memory die 201. A control die through silicon via (TSV) 278 may be used to route signals through a control die 211.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package.

As has been briefly discussed above, the control die 211 and the memory die 201 may be bonded together. Bond pads on each die 201, 211 may be used to bond the two dies together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat may also be applied. In embodiments using Cu-to-Cu bonding, the bond pads may be about 5 μm square and spaced from each other with a pitch of 5 μm to 5 μm. While this process is referred to herein as Cu-to-Cu bonding, this term may also apply even where the bond pads are formed of materials other than Cu.

When the area of bond pads is small, it may be difficult to bond the semiconductor dies together. The size of, and pitch between, bond pads may be further reduced by providing a film layer on the surfaces of the semiconductor dies including the bond pads. The film layer is provided around the bond pads. When the dies are brought together, the bond pads may bond to each other, and the film layers on the respective dies may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller sizes and pitches.

Some embodiments may include a film on surface of the dies 201, 211. Where no such film is initially provided, a space between the dies may be under filled with an epoxy or other resin or polymer. The under-fill material may be applied as a liquid which then hardens into a solid layer. This under-fill step protects the electrical connections between the dies 201, 211, and further secures the dies together. Various materials may be used as under-fill material, but in embodiments, it may be Hysol epoxy resin from Henkel Corp., having offices in California, USA.

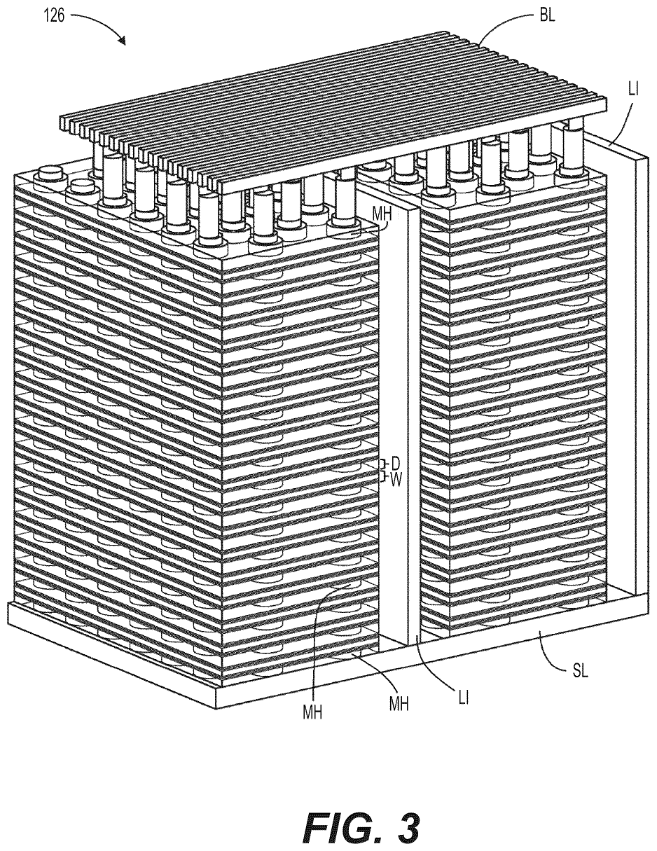

FIG. 3 is a perspective view of a portion of one example embodiment of a monolithic three dimensional memory array/structure architecture that can comprise memory structure 202, which includes a plurality non-volatile memory cells arranged as vertical NAND strings. For example, FIG. 3 shows a portion of one block of memory. The structure depicted includes a set of bit lines BL positioned above a stack of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements. One set of embodiments includes between 108-300 alternating dielectric layers and conductive layers. More or less than 108-300 layers can also be used. As will be explained below, in one embodiment the alternating dielectric layers and conductive layers are divided into four or more regions, or “fingers”, by local interconnects LI (optional). FIG. 3 shows two fingers and two local interconnects LI. Below the alternating dielectric layers and word line layers is a source line layer SL. Memory holes are formed in the stack of alternating dielectric layers and conductive layers. For example, one of the memory holes is marked as MH. Note that in FIG. 3, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three dimensional monolithic memory array that comprises memory structure 202 is provided below.

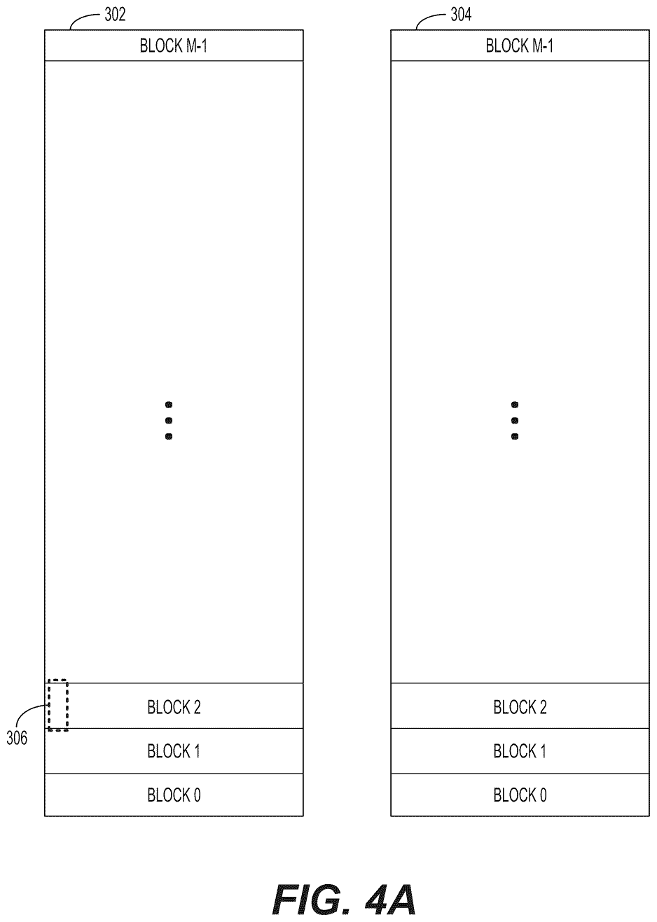

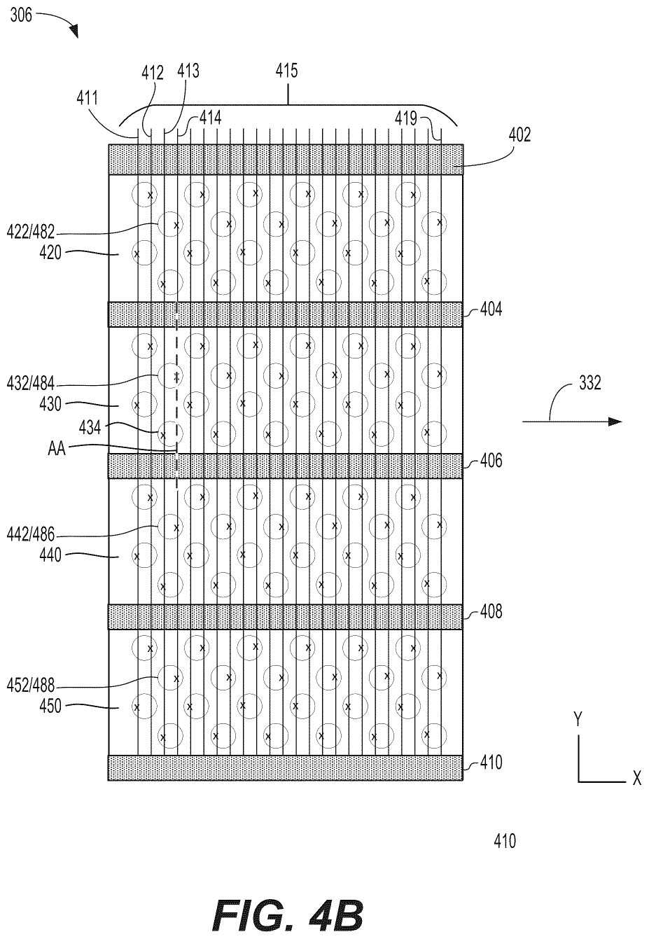

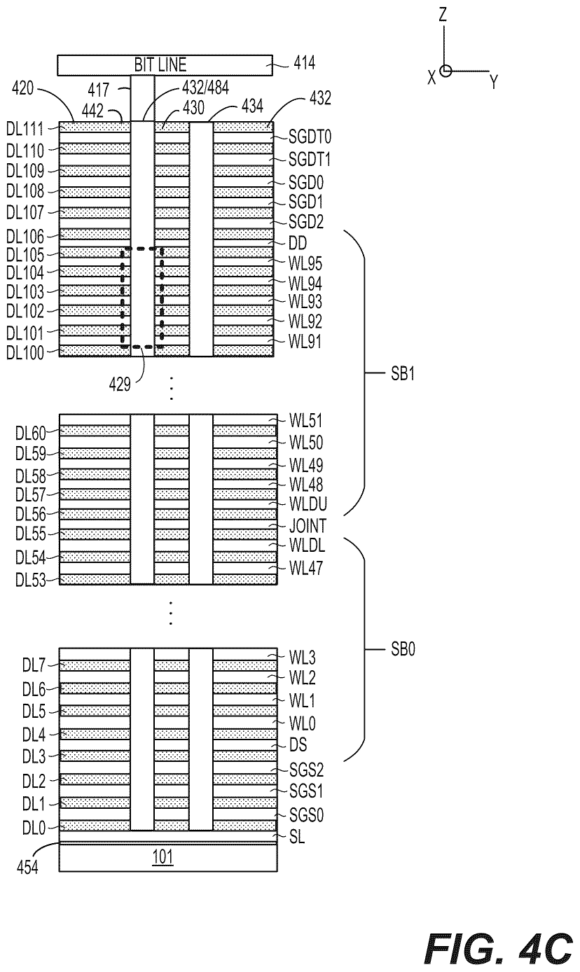

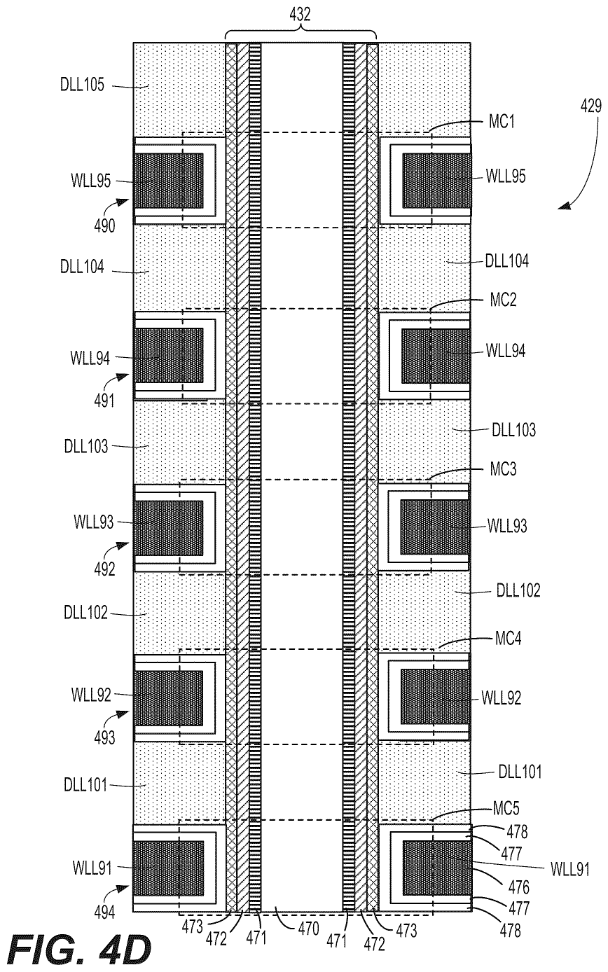

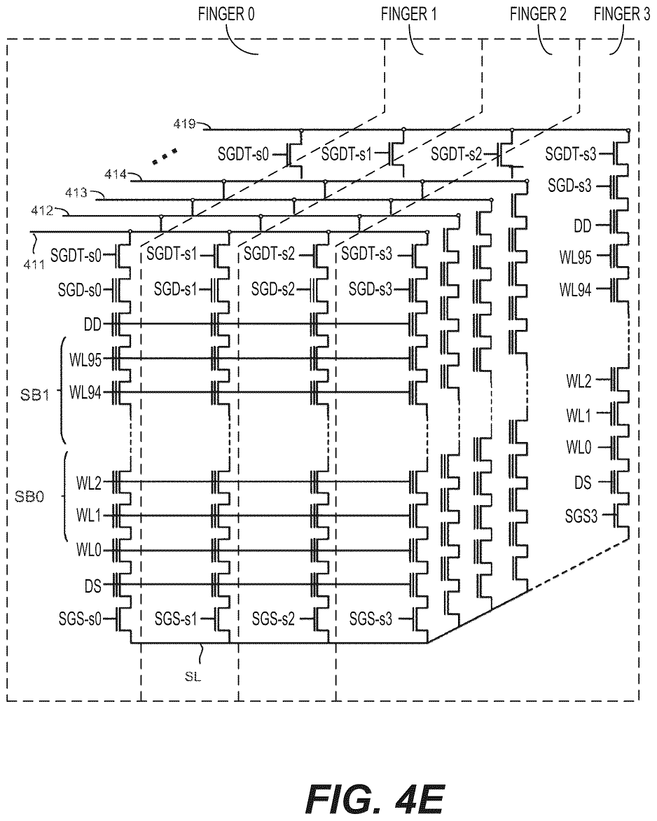

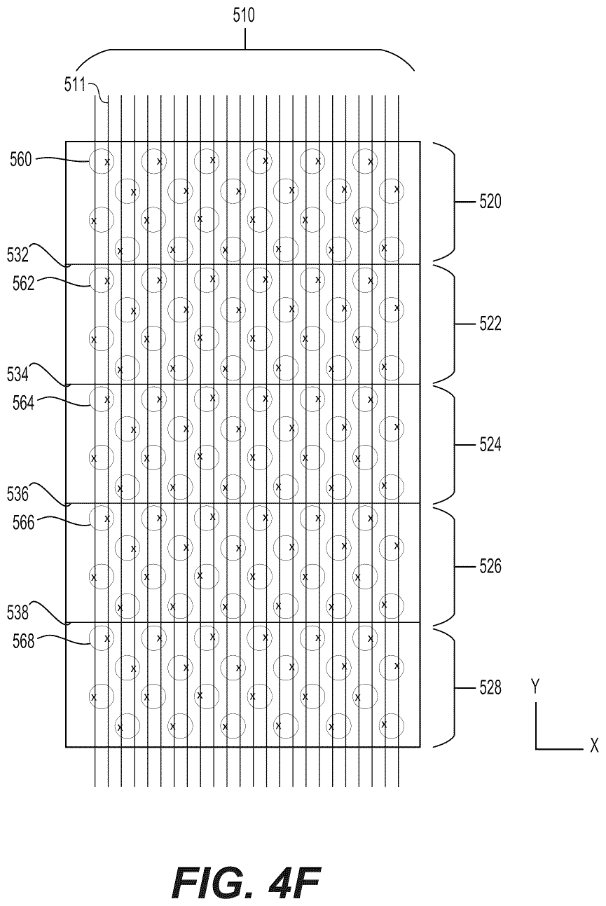

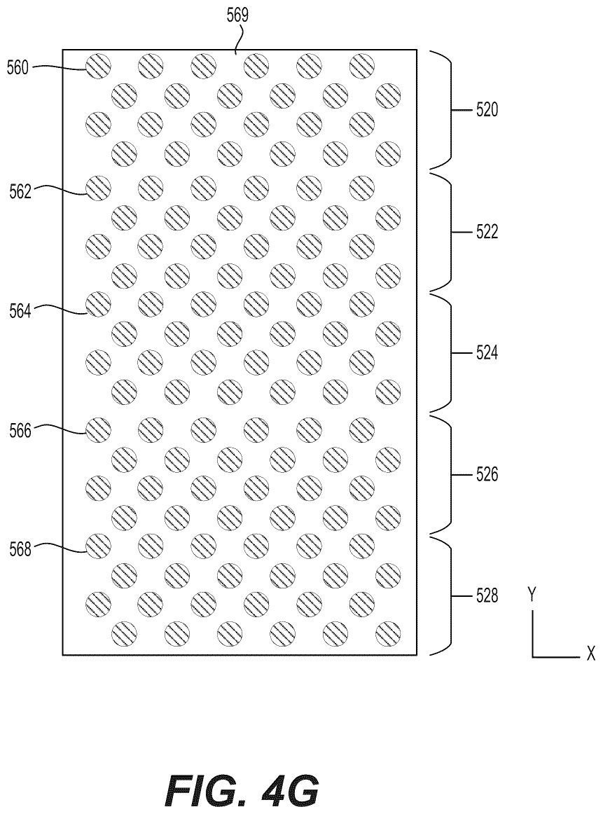

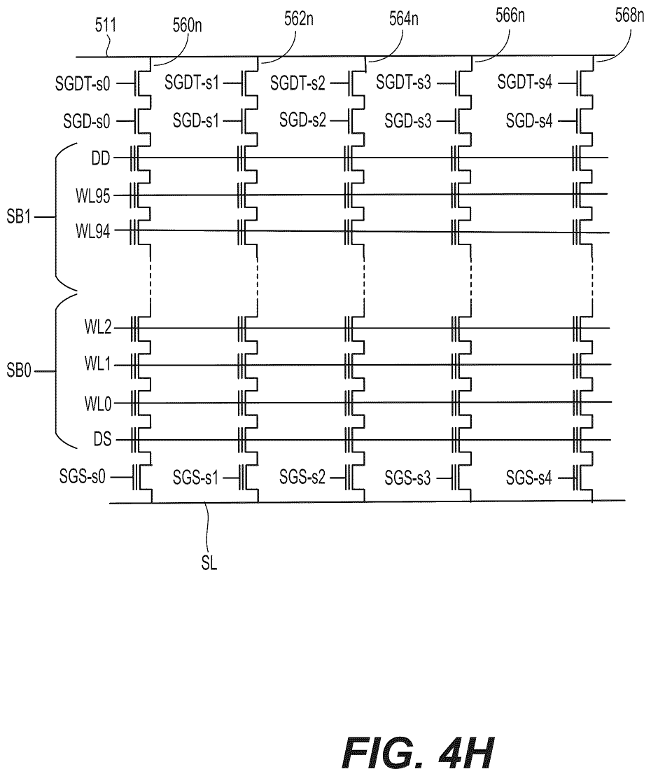

FIG. 4A is a block diagram explaining one example organization of memory structure 202, which is divided into two planes 302 and 304. Each plane is then divided into M blocks. In one example, each plane has about 2000 blocks. However, different numbers of blocks and planes can also be used. In one embodiment, a block of memory cells is a unit of erase. That is, all memory cells of a block are erased together. In other embodiments, blocks can be divided into sub-blocks and the sub-blocks can be the unit of erase. Memory cells can also be grouped into blocks for other reasons, such as to organize the memory structure to enable the signaling and selection circuits. In some embodiments, a block represents a group of connected memory cells as the memory cells of a block share a common set of word lines. For example, the word lines for a block are all connected to all of the vertical NAND strings for that block. Although FIG. 4A shows two planes 302/304, more or less than two planes can be implemented. In some embodiments, memory structure 202 includes eight planes.

FIGS. 4B-4E depict an example three dimensional (“3D”) NAND architecture that corresponds to the structure of FIG. 3 and can be used to implement memory structure 202 of FIGS. 2A and 2B. FIG. 4B is a block diagram depicting a top view of a portion of one block from memory structure 202. The portion of the block depicted in FIG. 4B corresponds to portion 306 in block 2 of FIG. 4A. As can be seen from FIG. 4B, the block depicted in FIG. 4B extends in the direction of 332. In one embodiment, the memory array has many layers; however, FIG. 4B only shows the top layer.

FIG. 4B depicts a plurality of circles that represent the vertical columns. Each of the vertical columns include multiple select transistors (also referred to as a select gate or selection gate) and multiple memory cells. In one embodiment, each vertical column implements a NAND string. For example, FIG. 4B depicts vertical columns 422, 432, 442 and 452. Vertical column 422 implements NAND string 482. Vertical column 432 implements NAND string 484. Vertical column 442 implements NAND string 486. Vertical column 452 implements NAND string 488. More details of the vertical columns are provided below. Since the block depicted in FIG. 4B extends in the direction of arrow 332, the block includes more vertical columns than depicted in FIG. 4B.

FIG. 4B also depicts a set of bit lines 415, including bit lines 411, 412, 413, 414, . . . 419. FIG. 4B shows twenty four bit lines because only a portion of the block is depicted. It is contemplated that more than twenty four bit lines connected to vertical columns of the block. Each of the circles representing vertical columns has an “x” to indicate its connection to one bit line. For example, bit line 414 is connected to vertical columns 422, 432, 442 and 452.

The block depicted in FIG. 4B includes a set of local interconnects 402, 404, 406, 408 and 410 that connect the various layers to a source line below the vertical columns. Local interconnects 402, 404, 406, 408 and 410 also serve to divide each layer of the block into four regions; for example, the top layer depicted in FIG. 4B is divided into regions 420, 430, 440 and 450, which are referred to as fingers or sub-blocks, as, in some embodiments, erase can be performed individually on these divisions. (In the following, these divisions will be referred to as “fingers”, with the term “sub-block” being used to refer to the upper and lower divisions of the 3D array structure as illustrated in FIG. 4C.) In the layers of the block that implement memory cells, the four regions are referred to as word line fingers that are separated by the local interconnects. In one embodiment, the word line fingers on a common level of a block are connect together to form a single word line. In another embodiment, the word line fingers on the same level are not connected together. In one example implementation, a bit line only connects to one vertical column in each of regions 420, 430, 440 and 450. In that implementation, each block has sixteen rows of active columns and each bit line connects to four rows in each block. In one embodiment, all of four rows connected to a common bit line are connected to the same word line (via different word line fingers on the same level that are connected together); therefore, the system uses the source side selection lines and the drain side selection lines to choose one (or another subset) of the four to be subjected to a memory operation (program, verify, read, and/or erase).

Although FIG. 4B shows each region having four rows of vertical columns, four regions and sixteen rows of vertical columns in a block, those exact numbers are an example implementation. Other embodiments may include more or less regions per block, more or less rows of vertical columns per region and more or less rows of vertical columns per block.

FIG. 4B also shows the vertical columns being staggered. In other embodiments, different patterns of staggering can be used. In some embodiments, the vertical columns are not staggered.

FIG. 4C depicts a portion of one embodiment of a three dimensional memory structure 202 showing a cross-sectional view along line AA of FIG. 4B. This cross sectional view cuts through vertical columns 432 and 434 and region 430 (see FIG. 4B). The structure of FIG. 4C includes: five drain side select layers SGDT0, SGDT1, SGD0, SGD1 and SGD2; three source side select layers SGS0, SGS1, and SGS2; four dummy word line layers DD, DS, WLDL and WLDU; and ninety six data word line layers WL0-WL95 for connecting to data memory cells. Other embodiments can implement more or less than five drain side select layers, more or less than three source side select layers, more or less than four dummy word line layers, and more or less than ninety six word lines. In one embodiment, SGD0, SGD1 and SGD2 are connected together, SGDT0 and SGDT1 are connected together, and SGS0, SG1 and SGS2 are connected together. In one embodiment, SGD0, SGD1 and SGD2 are used to select a NAND string or a finger, while SGDT0 and SGDT1 are used for erase using gate induced drain leakage (“GIDL”) generation.

Vertical columns 432 and 434 are depicted protruding through the drain side select layers, source side select layers, dummy word line layers and word line layers. In one embodiment, each vertical column comprises a vertical NAND string. For example, vertical column 432 comprises NAND string 484. Below the vertical columns and the layers listed below is substrate 101, an insulating film 454 on the substrate, and source line SL. The NAND string of vertical column 432 has a source end at a bottom of the stack and a drain end at a top of the stack. As in agreement with FIG. 4B, FIG. 4C show vertical column 432 connected to Bit Line 414 via connector 417. Local interconnects 404 and 406 are also depicted.

For ease of reference, drain side select layers, source side select layers, dummy word line layers and data word line layers collectively are referred to as the conductive layers. In one embodiment, the conductive layers are made from a combination of TiN and Tungsten. In other embodiments, other materials can be used to form the conductive layers, such as doped polysilicon, metal such as Tungsten or metal silicide. In some embodiments, different conductive layers can be formed from different materials. Between conductive layers are dielectric layers DL0-DL111. For example, dielectric layers DL104 is above word line layer WL94 and below word line layer WL95. In one embodiment, the dielectric layers are made from SiO2. In other embodiments, other dielectric materials can be used to form the dielectric layers.

The non-volatile memory cells are formed along vertical columns which extend through alternating conductive and dielectric layers in the stack. In one embodiment, the memory cells are arranged in NAND strings. The word line layers WL0-WL95 connect to memory cells (also called data memory cells). Dummy word line layers DD, DS, WLDL and WLDU connect to dummy memory cells. A dummy memory cell does not store and is not eligible to store host data (data provided from the host, such as data from a user of the host), while a data memory cell is eligible to store host data. In some embodiments, data memory cells and dummy memory cells may have a same structure. A dummy word line is connected to dummy memory cells. Drain side select layers SGD0, SGD1, and SGD2 are used to electrically connect and disconnect NAND strings from bit lines. Source side select layers SGS0, SGS1, and SGS2 are used to electrically connect and disconnect NAND strings from the source line SL.

To increase the density of data storage, block size can be increased by including more layers of word lines, increasing the height of the memory structure in the z-direction. As block size increases, this can lead to issues with block yield, block budget, the efficiency and speed of data allocation, and garbage collection. In some embodiments, a sub-block structure can be introduced to help address these issues by allowing erase and program at the sub-block level. FIG. 4C illustrates an example where the block is split into an upper sub-block SB1 and a lower sub-block SB1. Other embodiments can use larger numbers of such sub-blocks. In FIG. 4C, lower sub-block SB0 includes word lines layers WL0-WL47 and upper sub-block includes word line layers WL48-WL95. In the embodiment of FIG. 4C, the upper and lower sub-blocks are separated by a pair of dummy word lines WLDU and WLDL. Other embodiments may have more or less dummy word lines between sub-blocks and may additionally or alternatively include a non-programmable sub-block joint transistor of a different size or structure than the memory cell transistors.

FIG. 4D depicts a cross sectional view of region 429 of FIG. 4C that includes a portion of vertical column 432 (a memory hole). In one embodiment, the vertical columns are round; however, in other embodiments other shapes can be used. In one embodiment, vertical column 432 includes an inner core layer 470 that is made of a dielectric, such as SiO2. Other materials can also be used. Surrounding inner core 470 is polysilicon channel 471. Materials other than polysilicon can also be used. Note that it is the channel 471 that connects to the bit line and the source line. Surrounding channel 471 is a tunneling dielectric 472. In one embodiment, tunneling dielectric 472 has an ONO structure. Surrounding tunneling dielectric 472 is charge trapping layer 473, such as (for example) Silicon Nitride. Other memory materials and structures can also be used. The technology described herein is not limited to any particular material or structure.

FIG. 4D depicts dielectric layers DLL105, DLL104, DLL103, DLL102 and DLL101, as well as word line layers WLL95, WLL94, WLL93, WLL92, and WLL91. Each of the word line layers includes a word line region 476 surrounded by an aluminum oxide layer 477, which is surrounded by a blocking oxide layer 478. In other embodiments, the blocking oxide layer can be a vertical layer parallel and adjacent to charge trapping layer 473. The physical interaction of the word line layers with the vertical column forms the memory cells. Thus, a memory cell, in one embodiment, comprises channel 471, tunneling dielectric 472, charge trapping layer 473, blocking oxide layer 478, aluminum oxide layer 477 and word line region 476. For example, word line layer WLL95 and a portion of vertical column 432 comprise a memory cell MC1. Word line layer WLL94 and a portion of vertical column 432 comprise a memory cell MC2. Word line layer WLL93 and a portion of vertical column 432 comprise a memory cell MC3. Word line layer WLL92 and a portion of vertical column 432 comprise a memory cell MC4. Word line layer WLL91 and a portion of vertical column 432 comprise a memory cell MC5. In other architectures, a memory cell may have a different structure; however, the memory cell would still be the storage unit.

When a memory cell is programmed, electrons are stored in a portion of the charge trapping layer 473 which is associated with the memory cell. These electrons are drawn into the charge trapping layer 473 from the channel 471, through the tunneling dielectric 472, in response to an appropriate voltage on word line region 476. The threshold voltage (Vth) of a memory cell is increased in proportion to the amount of stored charge. In one embodiment, the programming is achieved through Fowler-Nordheim tunneling of the electrons into the charge trapping layer. During an erase operation, the electrons return to the channel or holes are injected into the charge trapping layer to recombine with electrons. In one embodiment, erasing is achieved using hole injection into the charge trapping layer via a physical mechanism such as GIDL.

FIG. 4E is a schematic diagram of a portion of the memory depicted in in FIGS. 3-4D. FIG. 4E shows physical data word lines WL0-WL95 running across the entire block. The structure of FIG. 4E corresponds to portion 306 in Block 2 of FIGS. 4A-D, including bit lines 411, 412, 413, 414,. 419. Within the block, in one embodiment, each bit line is connected to four NAND strings. As mentioned above with respect to FIG. 4C, in one embodiment, SGD0, SGD1 and SGD2 are connected together to operate as a single logical select gate that is represented in FIG. 4E as SGD (SGD-s0, SGD-s1, SGD-s2, SGD-s3); SGDT0 and SGDT1 are connected together to operate as a single logical gate that is represented in FIG. 4E as SGT (SGDT-s0, SGDT-s1, SGDT-s2, SGDT-s3); and SGS0, SG1 and SGS2 are connected together to operate as a single logical select gate that is represented in FIG. 4E as SGS (SGS-s0, SGS-s1, SGS-s2, SGS-s3).

The block can also be thought of as divided into four fingers. In one embodiment the data word line layers of each finger are connected together. In one embodiment, the drain side select layers (SGD0, SGD1 and SGD2) are electrically divided by local interconnects LI (see above) into four separate drain side select lines and gates (transistors) SGD-s0, SGD-s1, SGD-s2, SGD-s3 such that there is one per finger so that each finger can be independently selected. Similarly, the SGT layers are divided by local interconnects LI (see above) into four separate lines and gates (transistors) SGDT-s0, SGDT-s1, SGDT-s2, SGDT-s3 such that there is one per finger so that GIDL can be generated separately and independently for each finger. The source side select layers (SGS0, SGS1 and SGS2) are electrically divided by local interconnects LI (see above) into four separate source side select lines and gates (transistors) SGS-s0, SGS-s1, SGS-s2, SGS-s3 such that there is one per finger so that each finger can be independently selected.

Finger 0 corresponds to those vertical NAND strings controlled by SGD-s0 and SGS-s0, Finger 1 corresponds to those vertical NAND strings controlled by SGD-s1 and SGS-s1, Finger 2 corresponds to those vertical NAND strings controlled by SGD-s2 and SGS-s2, and Finger 3 corresponds to those vertical NAND strings controlled by SGD-s3 and SGS-s3.

FIG. 4F is a block diagram depicting a top view of a portion of one block from another embodiment of memory structure 202. In one embodiment, the memory structure has many layers; however, FIG. 4F only shows the top layer. The block of FIG. 4F is divided into five fingers 520, 522, 524, 526, and 528. The block depicted in FIG. 4F includes a set of dividers 532, 534, 536 and 538 that separate and electrically isolate the SDT, SGD and SGS layers, but not the data word line layers. That is, in one embodiment, the data word lines (WL0, WL1, WL95) are continuous and connected to all vertical columns (NAND strings) of the block.

FIG. 4F depicts a plurality of circles that represent the vertical columns. Each of the vertical columns include multiple select transistors and multiple memory cells. In one embodiment, each vertical column implements a NAND string. For example, FIG. 4F depicts vertical columns 560, 562, 564, 566 and 568. FIG. 4F also depicts a set of bit lines 510 (including bit line 511). Each of the circles representing vertical columns has an “x” to indicate its connection to one bit line. For example, bit line 511 is connected to vertical columns vertical columns 560, 562, 564, 566 and 568.

As mentioned above, dividers 532, 534, 536 and 538 separate and electrically isolate the SDT, SGD and SGS layers, but not the data word line layers. FIG. 4G is a top view of a data word line 569 layer showing a cutaway view of the vertical columns (e.g., NAND strings) 560, 562, 564, 566 and 568. The vertical columns are depicted as shaded circle. FIG. 4G shows that although the vertical columns (e.g., NAND strings) 560, 562, 564, 566 and 568 are divided into fingers 520, 522, 524, 526, and 528, the word line layer 569 (which can be any of WL0-WL95) is continuous and connected to all vertical columns (NAND strings) of the block.

FIG. 4H is a schematic diagram of a portion of the memory depicted in in FIGS. 4F and 4G. FIG. 4E shows physical data word lines WL0-WL95 running across the entire block. Within the block, in one embodiment, each bit line is connected to five NAND strings. The block is divided into five fingers 520, 522, 524, 526 and 528. In one embodiment, the data word line layers of each finger are connected together. In one embodiment, the drain side select layers (SGD0, SGD1 and SGD2) are electrically divided into five separate drain side select lines and gates (transistors) SGD-s0, SGD-s1, SGD-s2, SGD-s3 and SGD-s4 such that there is one per finger so that each finger can be independently selected. Similarly, the SGT layers are divided into four separate lines and gates (transistors) SGDT-s0, SGDT-s1, SGDT-s2, SGDT-s3 and SDT-s4 such that there is one per finger so that GIDL can be generated separately and independently for each finger. The source side select layers (SGS0, SGS1 and SGS2) are electrically divided into four separate source side select lines and gates (transistors) SGS-s0, SGS-s1, SGS-s2, SGS-s3 and SGS-s3 such that there is one per finger so that each finger can be independently selected.

Finger 520 includes those vertical NAND strings controlled by SGD-s0 and SGS-s0. For example, finger 520 includes NAND string 560 n which corresponds to vertical column 560. Finger 522 includes those vertical NAND strings controlled by SGD-s1 and SGS-s1. For example, finger 522 includes NAND string 562 n which corresponds to vertical column 562. Finger 524 includes those vertical NAND strings controlled by SGD-s2 and SGS-s2. For example, finger 524 includes NAND string 564 n which corresponds to vertical column 564. Finger 526 includes those vertical NAND strings controlled by SGD-s3 and SGS-s3. For example, finger 526 includes NAND string 566 n which corresponds to vertical column 566. Finger 528 includes those vertical NAND strings controlled by SGD-s4 and SGS-s4. For example, finger 528 includes NAND string 568 n which corresponds to vertical column 568.

Although the example memories of FIGS. 3-4H are three dimensional memory structure that includes vertical NAND strings with charge-trapping material, other (2D and 3D) memory structures can also be used with the technology described herein.

The memory systems discussed above can be erased, programmed and read. At the end of a successful programming process (with verification), the threshold voltages of the memory cells should be within one or more distributions of threshold voltages for programmed memory cells or within a distribution of threshold voltages for erased memory cells, as appropriate. FIG. 5 is a graph of threshold voltage versus number of memory cells, and illustrates example threshold voltage distributions for the memory array when each memory cell stores three bits of data. Other embodiments, however, may use other data capacities per memory cell (e.g., such as one, two, four, or five bits of data per memory cell). FIG. 5 shows eight threshold voltage distributions, corresponding to eight data states. For a data state N, that data state N has higher threshold voltages than data state N−1 and lower threshold voltages than data state N+1. The first threshold voltage distribution (data state) S0 represents memory cells that are erased. The other seven threshold voltage distributions (data states) S1-S7 represent memory cells that are programmed and, therefore, are also called programmed states or programmed data states. In some embodiments, data states S1-S7 can overlap, with controller 120 relying on error correction to identify the correct data being stored.

FIG. 5 shows seven read reference voltages, Vr1, Vr2, Vr3, Vr4, Vr5, Vr6, and Vr7 for reading data from memory cells. By testing (e.g., performing sense operations) whether the threshold voltage of a given memory cell is above or below the seven read reference voltages, the system can determine what data state (i.e., S0, S1, S2, S3, . . . ) a memory cell is in.

FIG. 5 also shows seven verify reference voltages, Vv1, Vv2, Vv3, Vv4, Vv5, Vv6, and Vv7 (also referred to as verify target voltages). When programming memory cells to data state S1, the system will test whether those memory cells have a threshold voltage greater than or equal to Vv1. When programming memory cells to data state S2, the system will test whether the memory cells have threshold voltages greater than or equal to Vv2. When programming memory cells to data state S3, the system will determine whether memory cells have their threshold voltage greater than or equal to Vv3. When programming memory cells to data state S4, the system will test whether those memory cells have a threshold voltage greater than or equal to Vv4. When programming memory cells to data state S5, the system will test whether those memory cells have a threshold voltage greater than or equal to Vv5. When programming memory cells to data state S6, the system will test whether those memory cells have a threshold voltage greater than or equal to Vv6. When programming memory cells to data state S7, the system will test whether those memory cells have a threshold voltage greater than or equal to Vv7.

In one embodiment, known as full sequence programming, memory cells can be programmed from the erased data state S0 directly to any of the programmed data states S1-S7. For example, a population of memory cells to be programmed may first be erased so that all memory cells in the population are in erased data state S0. Then, a programming process is used to program memory cells directly into data states S1, S2, S3, S4, S5, S6, and/or S7. For example, while some memory cells are being programmed from data state S0 to data state S1, other memory cells are being programmed from data state S0 to data state S2 and/or from data state S0 to data state S3, and so on. The arrows of FIG. 5 represent the full sequence programming. The technology described herein can also be used with other types of programming in addition to full sequence programming including (but not limited to) multiple stage/phase programming.

Each threshold voltage distribution (data state) of FIG. 5 corresponds to predetermined values for the set of data bits stored in the memory cells. The specific relationship between the data programmed into the memory cell and the threshold voltage levels of the memory cell depends upon the data encoding scheme adopted for the memory cells. In one embodiment, data values are assigned to the threshold voltage ranges using a Gray code assignment so that if the threshold voltage of a memory erroneously shifts to its neighboring physical state, only one bit will be affected.

FIG. 6 is a table describing one example of an assignment of data values to data states. In the table of FIG. 6, S0=111 (erased state), S1=110, S2=100, S3=000, S4=010, S5=011, S6=001 and S7=101. Other encodings of data can also be used. No particular data encoding is required by the technology disclosed herein. In one embodiment, when a block is subjected to an erase operation, all memory cells are moved to data state S0, the erased state.

In general, during verify operations and read operations, the selected word line is connected to a voltage (one example of a reference signal), a level of which is specified for each read operation (e.g., see read reference voltages Vr1, Vr2, Vr3, Vr4, Vr5, Vr6, and Vr7, of FIG. 5) or verify operation (e.g. see verify reference voltages Ev, Vv1, Vv2, Vv3, Vv4, Vv5, Vv6, and Vv7 of FIG. 5) in order to determine whether a threshold voltage of the concerned memory cell has reached such level. After applying the word line voltage, the conduction current of the memory cell is measured to determine whether the memory cell turned on (conducted current) in response to the voltage applied to the word line. If the conduction current is measured to be greater than a certain value, then it is assumed that the memory cell turned on and the voltage applied to the word line is greater than the threshold voltage of the memory cell. If the conduction current is not measured to be greater than the certain value, then it is assumed that the memory cell did not turn on and the voltage applied to the word line is not greater than the threshold voltage of the memory cell. During a read or verify process, the unselected memory cells are provided with one or more read pass voltages (also referred to as bypass voltages) at their control gates so that these memory cells will operate as pass gates (e.g., conducting current regardless of whether they are programmed or erased).

There are many ways to measure the conduction current of a memory cell during a read or verify operation. In one example, the conduction current of a memory cell is measured by the rate it discharges or charges a dedicated capacitor in the sense amplifier. In another example, the conduction current of the selected memory cell allows (or fails to allow) the NAND string that includes the memory cell to discharge a corresponding bit line. The voltage on the bit line is measured after a period of time to see whether it has been discharged or not. Note that the technology described herein can be used with different methods known in the art for verifying/reading. Other read and verify techniques known in the art can also be used.

One technique to erase memory cells in some memory devices is to bias a p-well (or other types of) substrate to a high voltage to charge up a NAND channel. An erase enable voltage (e.g., a low voltage) is applied to control gates of memory cells while the NAND channel is at a high voltage to erase the non-volatile storage elements (memory cells). Herein, this is referred to as p-well erase.

Another approach to erasing memory cells is to generate gate induced drain leakage (GIDL) current to charge up the NAND string channel. An erase enable voltage is applied to control gates of the memory cells, while maintaining the NAND string channel potential to erase the memory cells. Herein, this is referred to as GIDL erase. Both p-well erase and GIDL erase may be used to lower the threshold voltage (Vt) of memory cells.

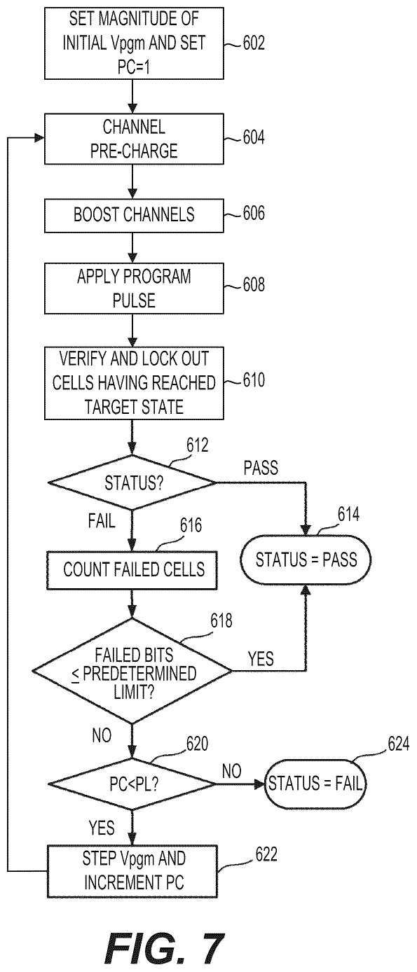

FIG. 7 is a flowchart describing one embodiment of a process for programming that is performed by memory die 200 and/or integrated assembly 207. In one example embodiment, the process of FIG. 7 is performed on memory die 200 using the one or more control circuits (e.g., system control logic 260, column control circuitry 210, row control circuitry 220) discussed above. In one example embodiment, the process of FIG. 7 is performed by integrated memory assembly 207 using the one or more control circuits (e.g., system control logic 260, column control circuitry 210, row control circuitry 220) of control die 211 to program memory cells on memory die 201. The process includes multiple loops, each of which includes a program phase and a verify phase. The process of FIG. 7 is performed to implement the full sequence programming, as well as other programming schemes including multi-stage programming. When implementing multi-stage programming, the process of FIG. 7 is used to implement any/each stage of the multi-stage programming process.

Typically, the program voltage applied to the control gates (via a selected data word line) during a program operation is applied as a series of program pulses (e.g., voltage pulses). Between programming pulses are a set of verify pulses (e.g., voltage pulses) to perform verification. In many implementations, the magnitude of the program pulses is increased with each successive pulse by a predetermined step size. In step 602 of FIG. 7, the program voltage (Vpgm) is initialized to the starting magnitude (e.g., ^{~}12-20V or another suitable level) and a program counter PC maintained by state machine 262 is initialized at 1.

In one embodiment, the set of memory cells selected to be programmed (referred to herein as the selected memory cells) are programmed concurrently and are all connected to the same data word line (the selected word line). There will likely be other memory cells that are not selected for programming (unselected memory cells) that are also connected to the selected word line. That is, the selected word line will also be connected to memory cells that are supposed to be inhibited from programming. Additionally, as memory cells reach their intended target data state, they will be inhibited from further programming. Those NAND strings (e.g., unselected NAND strings) that include memory cells connected to the selected word line that are to be inhibited from programming have their channels boosted to inhibit programming. When a channel has a boosted voltage, the voltage differential between the channel and the word line is not large enough to cause programming. To assist in the boosting, in step 604 the storage system will pre-charge channels of NAND strings that include memory cells connected to the selected word line that are to be inhibited from programming. In step 606, NAND strings that include memory cells connected to the selected word line that are to be inhibited from programming have their channels boosted to inhibit programming. Such NAND strings are referred to herein as “unselected NAND strings.” In one embodiment, the unselected data word lines receive one or more boosting voltages (e.g., ^{~}7-11 volts) to perform boosting schemes. A program inhibit voltage is applied to the bit lines coupled the unselected NAND string. One boosting mechanism, local self-boosting or LSB, is discussed in more detail below.

In step 608, a program pulse (e.g., voltage pulse) of the program signal Vpgm is applied to the selected word line (the data word line selected for programming). If a memory cell on a NAND string should be programmed, then the corresponding bit line is biased at a program enable voltage, in one embodiment. Herein, such a NAND string is referred to as a “selected NAND string.” In step 608, the program pulse is concurrently applied to all memory cells connected to the selected word line so that all of the memory cells connected to the selected word line are programmed concurrently (unless they are inhibited from programming). That is, they are programmed at the same time or during overlapping times (both of which are considered concurrent). In this manner all the memory cells connected to the selected word line will concurrently have their Vt change, unless they are inhibited from programming.

In step 610, memory cells that have reached their target states are locked out from further programming. Step 610 may include performing verifying at one or more verify reference levels. In one embodiment, the verification process is performed by testing whether the threshold voltages of the memory cells selected for programming have reached the appropriate verify reference voltage.

In step 610, a memory cell may be locked out after the memory cell has been verified (by a test of the Vt) that the memory cell has reached its target state. If, in step 612, it is determined that all of the memory cells have reached their target threshold voltages (pass), the programming process is complete and successful because all selected memory cells were programmed and verified to their target states. A status of “PASS” is reported in step 614. Otherwise, if, in step 612, it is determined that not all the memory cells have reached their target threshold voltages (fail), then the programming process continues to step 616.

In step 616, the system counts the number of memory cells that have not yet reached their respective target Vt distribution. That is, the system counts the number of memory cells that have, so far, failed to reach their target state. This counting can be done by the state machine 262, the memory controller 120, or other logic. In one implementation, each of the sense blocks will store the status (pass/fail) of their respective cells. In one embodiment, there is one total count, which reflects the total number of memory cells currently being programmed that have failed the last verify step. In another embodiment, separate counts are kept for each data state.

In step 618, it is determined whether the count from step 616 is less than or equal to a predetermined limit. In one embodiment, the predetermined limit is the number of bits that can be corrected by error correction codes (ECC) during a read process for a page (e.g., the unit of programming and the unit of reading) of memory cells. If the number of failed cells is less than or equal to the predetermined limit, than the programming process can stop and a status of “PASS” is reported in step 614. In this situation, enough memory cells programmed correctly such that the few remaining memory cells that have not been completely programmed can be corrected using ECC during the read process. In some embodiments, the predetermined limit used in step 618 is below the number of bits that can be corrected by error correction codes (ECC) during a read process to allow for future/additional errors. When programming less than all of the memory cells for a page, or comparing a count for only one data state (or less than all states), than the predetermined limit can be a pro-rata (or other) portion of the number of bits that can be corrected by ECC during a read process for the page of memory cells. In some embodiments, the limit is not predetermined. Instead, it changes based on the number of errors already counted for the page, the number of program-erase cycles performed or other criteria.

If the number of failed memory cells is not less than the predetermined limit, than the programming process continues at step 620 and the program counter PC is checked against the program limit value (PL). Examples of program limit values include 1, 12, 16, 20 and 30; however, other values can be used. If the program counter PC is not less than the program limit value PL, then the program process is considered to have failed and a status of FAIL is reported in step 624. If the program counter PC is less than the program limit value PL, then the process continues at step 622 during which time the Program Counter PC is incremented by 1 and the program voltage Vpgm is stepped up to the next magnitude. For example, the next pulse will have a magnitude greater than the previous pulse by a step size (e.g., a step size of 0.1-1.0 volts). After step 622, the process loops back to step 604 and another program pulse is applied to the selected word line so that another iteration (steps 604-622) of the programming process of FIG. 7 is performed.

Because it is possible that errors can occur when programming or reading, and errors can occur while storing data (e.g., due to electrons drifting, data retention issues or other phenomenon), error correction is used with the programming of data. Memory systems often use Error Correction Codes (ECC) to protect data from corruption. Many ECC coding schemes are well known in the art. These conventional error correction codes are especially useful in large scale memories, including flash (and other non-volatile) memories, because of the substantial impact on manufacturing yield and device reliability that such coding schemes can provide, rendering devices that have a few non-programmable or defective cells as useable. Of course, a tradeoff exists between the yield savings and the cost of providing additional memory cells to store the code bits (i.e., the code “rate”). As such, some ECC codes are better suited for flash memory devices than others. Generally, ECC codes for flash memory devices tend to have higher code rates (i.e., a lower ratio of code bits to data bits) than the codes used in data communications applications (which may have code rates as low as ½). Examples of well-known ECC codes commonly used in connection with flash memory storage include Reed-Solomon codes, other BCH codes, Hamming codes, and the like. Sometimes, the error correction codes used in connection with flash memory storage are “systematic,” in that the data portion of the eventual code word is unchanged from the actual data being encoded, with the code or parity bits appended to the data bits to form the complete code word.

The particular parameters for a given error correction code include the type of code, the size of the block of actual data from which the code word is derived, and the overall length of the code word after encoding. For example, a typical BCH code applied to a sector of 512 bytes (4096 bits) of data can correct up to four error bits, if at least 60 ECC or parity bits are used. Reed-Solomon codes are a subset of BCH codes, and are also commonly used for error correction. For example, a typical Reed-Solomon code can correct up to four errors in a 512 byte sector of data, using about 72 ECC bits. In the flash memory context, error correction coding provides substantial improvement in manufacturing yield, as well as in the reliability of the flash memory over time.

In some embodiments, memory controller 120 receives host data (also referred to as user data or data from an entity external to the memory system), also referred to as information bits, that is to be stored non-volatile memory structure 202. The informational bits are represented by the matrix i=[1 0] (note that two bits are used for example purposes only, and many embodiments have code words longer than two bits). An error correction coding process (such as any of the processes mentioned above or below) is implemented by ECC engine 158 of memory controller 120 in which parity bits are added to the informational bits to provide data represented by the matrix or code word v=[1 0 1 0], indicating that two parity bits have been appended to the data bits. Other techniques can be used that map input data to output data in more complex manners. For example, low density parity check (LDPC) codes, also referred to as Gallager codes, can be used. In practice, such LDPC codes are typically applied (e.g., by ECC engine 158) to multiple pages encoded across a number of memory cells, but they do not need to be applied across multiple pages. The data bits can be mapped to a logical page and stored in memory structure 202 by programming one or more memory cells to one or more programming states, which corresponds to v.

In one embodiment, programming serves to raise the threshold voltage of the memory cells to one of the programmed data states S1-S7, and erasing serves to lower the threshold voltage of the memory cells to the Erase data state S0.

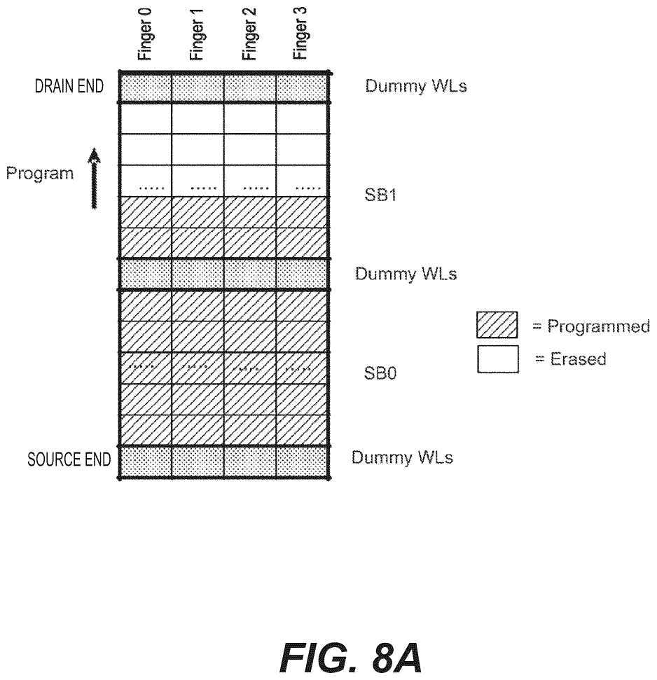

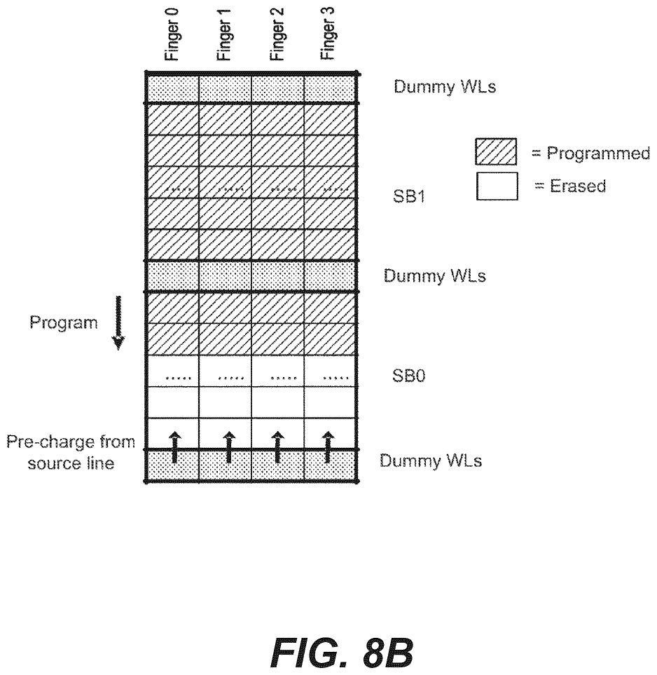

When programming the memory cells as described above, prior to applying a program pulse at step 608 of FIG. 7, if a memory cell should be programmed, then the corresponding bit line is grounded, or, more generally, set to a program enable voltage. On the other hand, if the memory cell should remain at its current threshold voltage, then the corresponding bit line is connected to a program inhibit level, such as Vdd. In many embodiments, the word lines of an erased block are programmed stating at the source end with word line word line WL0 of FIG. 4A-4H. As the other memory cells of the columns between the selected word line and the bit line are erased, this allows for the level on the bit line to be applied to the memory cells of the selected word line uniformly, whereas if any of the intermediate memory cells were programmed, this pre-charging of the memory cells could be blocked. The word lines of the block are then sequentially written in an order working from the source side on the bottom towards the bit lines at the drain end of the NAND strings. This is illustrated schematically in FIG. 8A.

FIG. 8A is a simplified version of FIGS. 4A-4H describing one embodiment of a process for programming word lines of a block of memory cells sequentially from the source end (at bottom) towards the drain end in “normal order programming”, or NOP. The block is shown at a stage where the lower sub-block SB0 is programmed and the first few word lines of the upper sub-block SB1 have been written. The stippled regions at top represent the select gates and any dummy word lines at the ends of the strings through which the NAND strings are respectively connected to the bit and source lines on either end. The central stippled region represents any dummy word lines in the joint region between sub-blocks SB1 and SB2, such as WLDL and WLDU of FIG. 4C, as well as any joint transistors between the sub-blocks, if these are included in the structure. In many embodiments, the dummy word lines at the source and drain ends, as well the inter-sub-block dummy word lines, if included, are not rewritten in a standard programming operation.

In embodiments where the memory system allows program and erase at the sub-block level, the state of one sub-block can affect the operation of the other sub-block. Whether or not the lower sub-block SB0 is programmed, the standard programming order illustrated in FIG. 8A can be used on upper sub-block S1 as the lower sub-block SB0 is not between the bit lines and the selected word line. Similarly, if the upper sub-block SB1 is erased, as after a full physical block erase, normal order programming can be used for the lower sub-block SB0. However, in the case where the upper sub-block SB1 is programmed, but the lower sub-block SB0 has been erased and is to be programmed, the programming order can be altered in some embodiments.

FIG. 8B illustrates the case where the upper sub-block SB1 is programmed, and the lower sub-block is to be programmed. Normal order programming (programming up from the source side) for the lower sub-block SB0 creates problems when the upper sub-block SB1 is programmed as the pre-charge from the bit line side can be obstructed. The conventional order can also lead to other problems, such as program disturb concerns for the data programmed in the upper sub-block SB1. To help alleviate these problems, FIG. 8B illustrates an embodiment that uses a “mirror” or reverse order of programming (ROP), where the word lines of the lower sub-block SB0 are programmed sequentially from the middle downwards. In some embodiments, columns can be pre-charged form the source line, rather than the bit line, to either a program inhibit or program enable level, avoiding the problems that can arise when pre-charging from the top side when the upper sub-block SB1 is programmed.

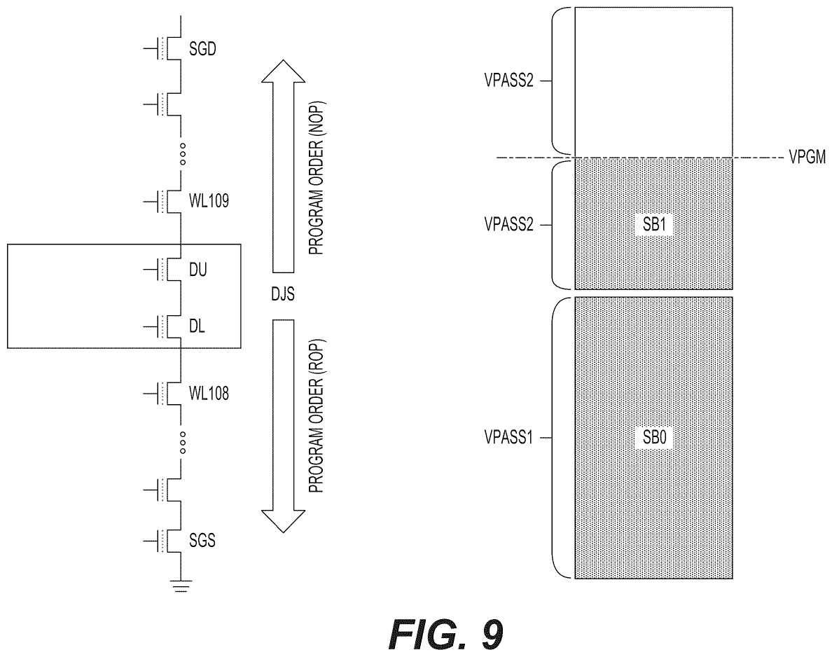

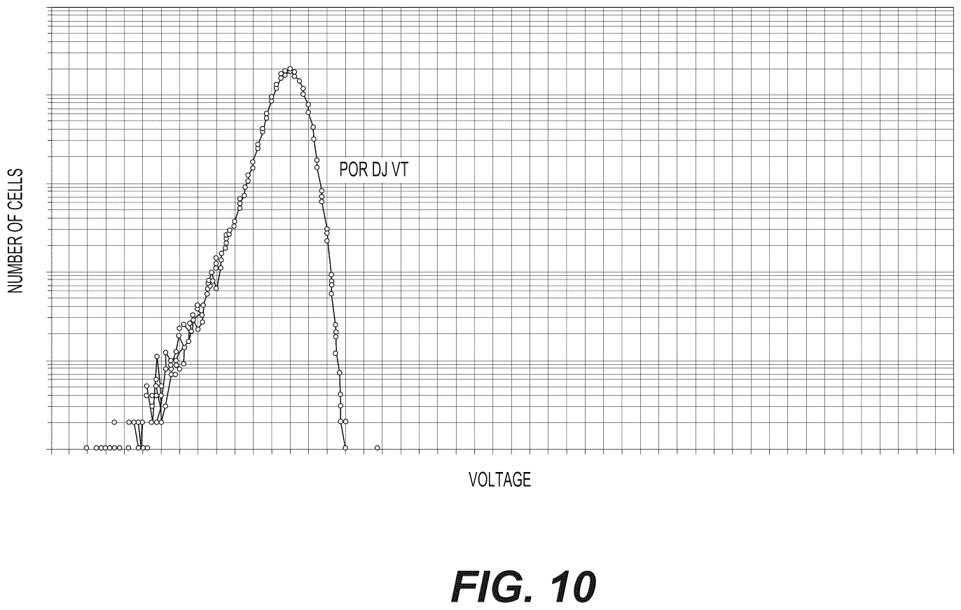

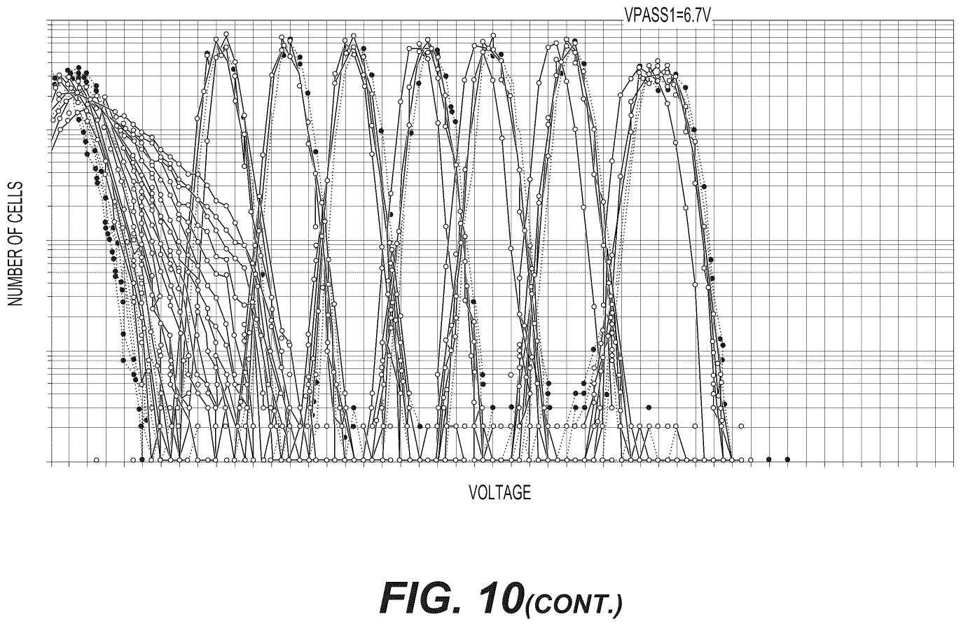

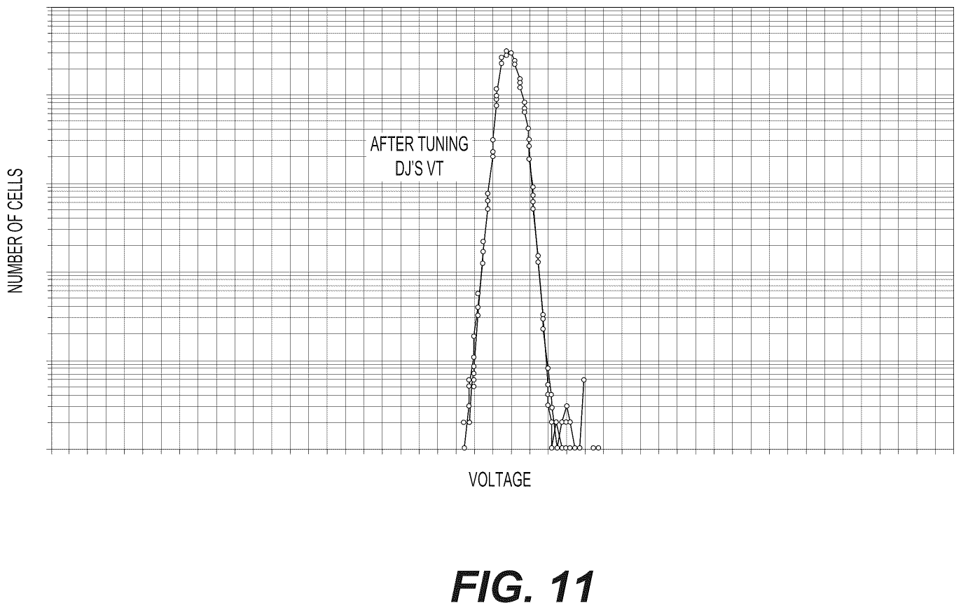

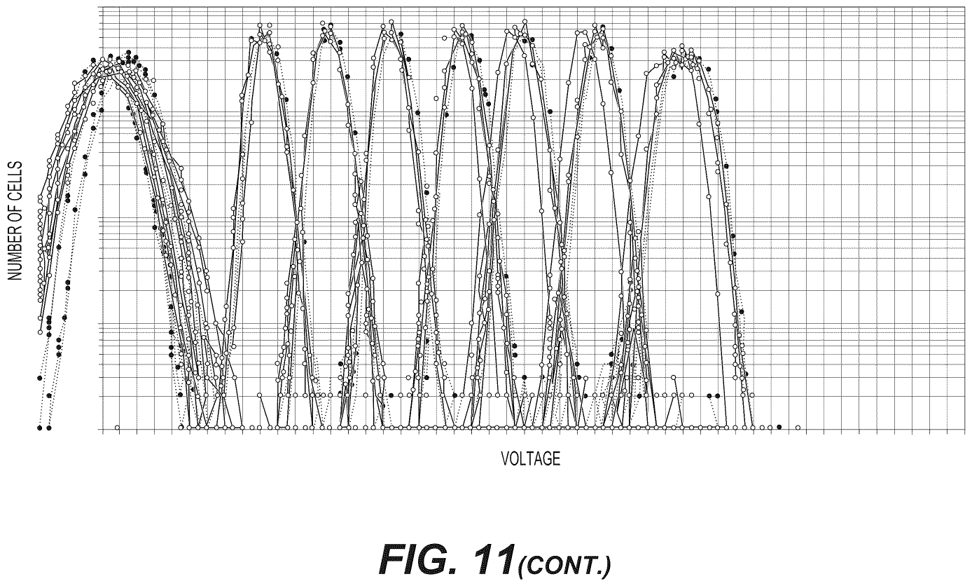

As discussed, when operating the memory apparatus in a sub-block mode (SBM), the threshold voltage of memory cells connected to dummy word lines adjacent the joint region being too low may adversely affect programming of the other memory cells of the sub-blocks. FIG. 9 shows a block of memory cells divided into a first sub-block SB0 vertically disposed below a second sub-block SB1 along with a corresponding circuit diagram of one memory hole of the block with memory cells connected to dummy word lines at the joint or interface region between the sub-blocks and illustrates a programming order of each sub-block as well as the voltages to word lines of each sub-block applied during programming. With the boosting scheme in such a sub-block arrangement, the threshold voltage of the memory cells connected to the dummy word lines (DJ) needs to be fined tuned. If the threshold voltage of the memory cells connected to the dummy word lines is not ideal, there will be severe boost leakage, due to the low pass voltage VPASS1 values be used in unselected sub-block. FIG. 10 shows a threshold voltage distribution for a non-ideal threshold voltage of the memory cells connected to the dummy word lines (POR DJ Vt) along with an associated plot of the threshold voltage distributions of the memory cells connected to data word lines of the sub-blocks. As shown, the threshold voltage distributions overlap of the erased or S0 data state and A or S1 data state (Er2A) will be problematic for the memory cells connected to many of the word lines after program. To improve the boosting, the threshold voltage of the memory cells connected to the dummy word lines at the interface region need to be programmed higher. In the way, the memory cells connected to the dummy word lines (DJ) will behave like select gates, which will cut off the channel communication between the first sub-block SB0 and the second sub-block SB1. FIG. 11 shows a threshold voltage distribution for a tuned threshold voltage (i.e., a higher threshold voltage) of the memory cells connected to the dummy word lines (After tuning DJ's Vt) along with an associated plot of the threshold voltage distributions of the memory cells connected to data word lines of the sub-blocks.

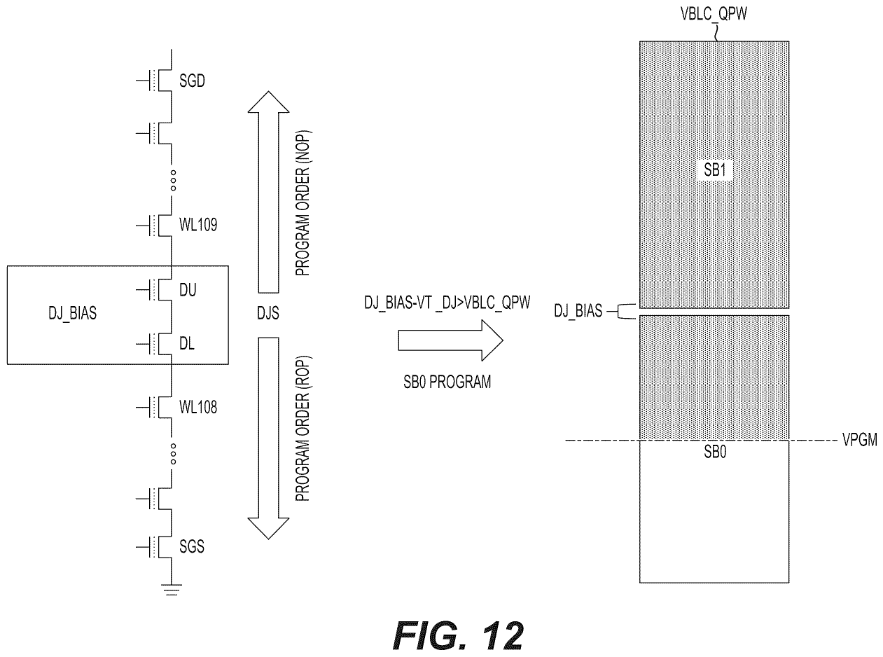

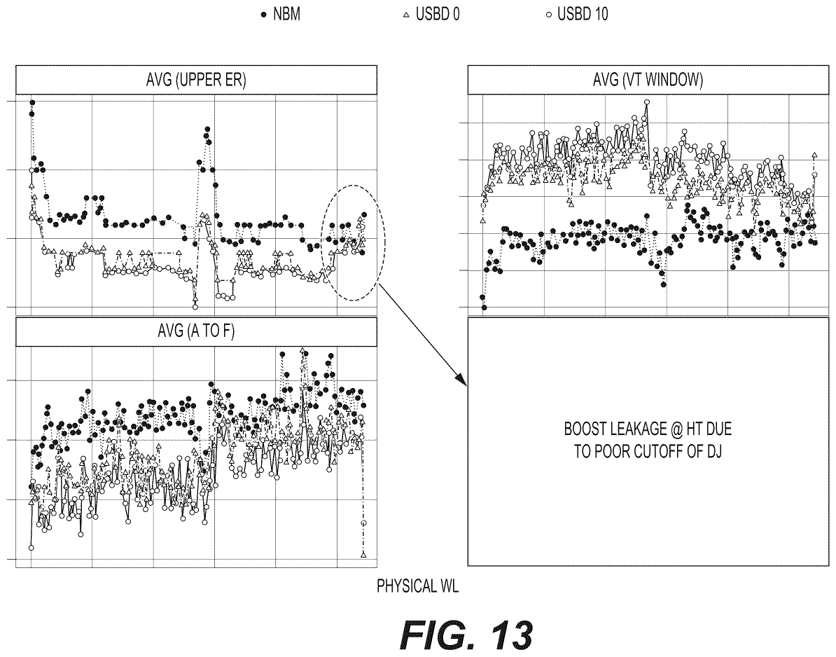

FIG. 12 shows another block of memory cells divided into a first sub-block SB0 vertically disposed below a second sub-block SB1 along with a corresponding circuit diagram of one memory hole of the block with memory cells connected to dummy word lines at the joint or interface region between the sub-blocks and illustrates voltages (e.g., VBLC_QPW) applied to a bit line connected to each of the memory holes of the block during programming along with a voltage or bias, DJ_Bias applied to the dummy word lines during programming of the first sub-block. FIG. 13 shows plots of an erase upper tail, threshold voltage window, and threshold voltage distribution width versus physical word line for memory cells of blocks cycled 3000 cycles at high temperature. In the example discussed above, DJ_Bias, should be larger than the tuned threshold voltage Vt of the memory cells connected to the dummy word lines (DJ), to be more specific, the DJ_Bias during a program operation should be larger than the threshold voltage of the memory cells connected to the dummy word lines (DJ) Vt_DJ plus a stepped up voltage (e.g., VBLC_QPW) applied to the bit lines to slow down programming of the memory cells connected thereto. The reason is during the programming or program operation of the first sub-block SB0, the signal stepped up voltage VBLC_QPW shall be able to pass down to the channel of the first sub-block SB0. If DJ_Bias is lower than the target values, then the channel of the first sub-block SB0 will be floating, the signal of the bit line cannot pass down to the sub-block SB0 channel. However, this will mean the cut-off of the memory cells connected to the dummy word lines (DJ) will be weak, even after tuning of their threshold voltage. This weak cut-off will show the consequence at high temperature (HT), as can be seen in FIG. 13. At HT, physical word line (WL) 200 and beyond will show high Er2A (overlap) because of the boost leak after sub-block one SB1 program.

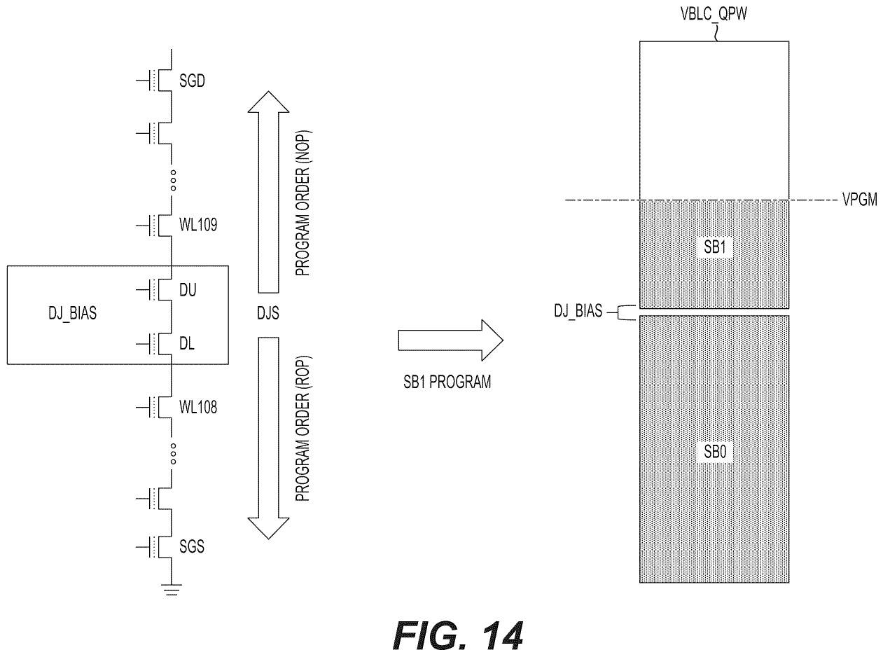

FIG. 14 shows another block of memory cells divided into a first sub-block SB0 vertically disposed below a second sub-block SB1 along with a corresponding circuit diagram of one memory hole of the block with memory cells connected to dummy word lines at the joint or interface region between the sub-blocks and illustrates voltages VBLC_QPW applied to a bit line connected to each of the memory holes of the block during programming along with a voltage or bias, DJ_BIAS applied to the dummy word lines during programming of the second sub-block. During the during program operation of the second sub-block SB1, the bit line signal (e.g., stepped up voltage VBLC_QPW) does not need to pass down to the first sub-block SB0 channel. Therefore, DJ bias now can be smaller than the threshold voltage of the memory cells connected to the dummy word lines (DJ). In this fashion, it will mean a strong cut-off between the first sub-block SB0 and the second sub-block SB1, and it is expected that boosting will be improved for the second sub-block SB1.

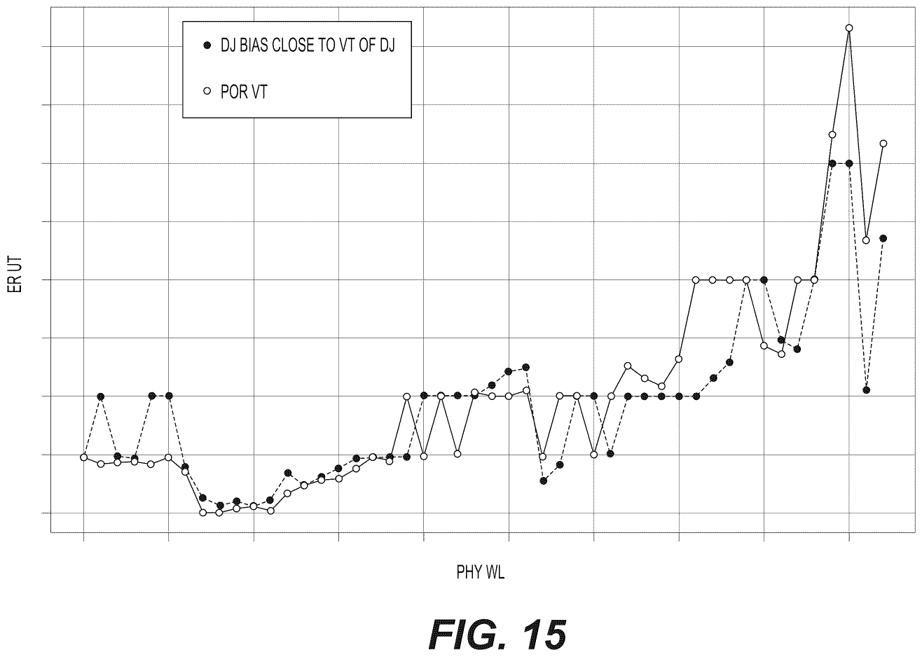

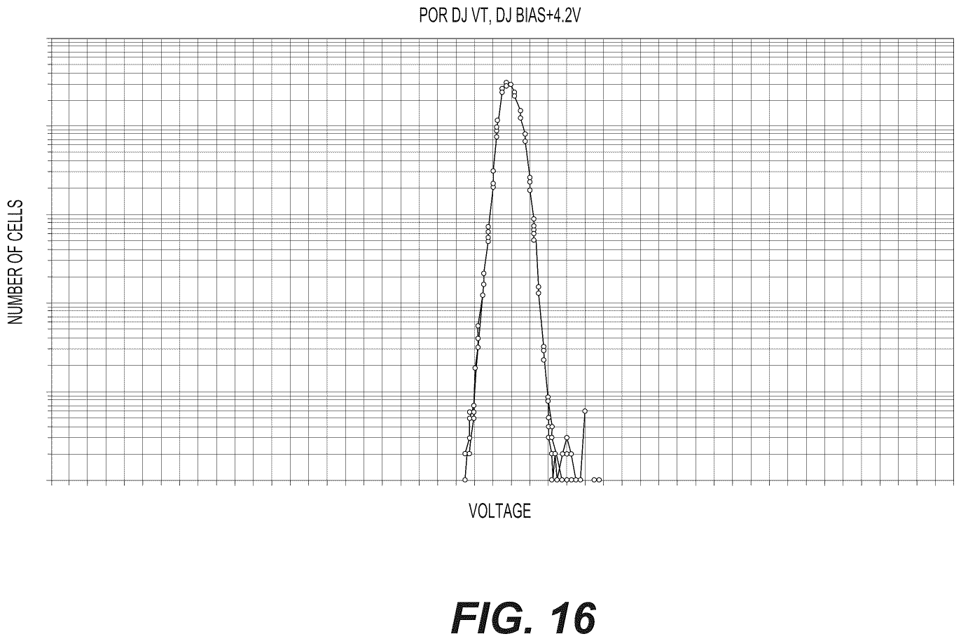

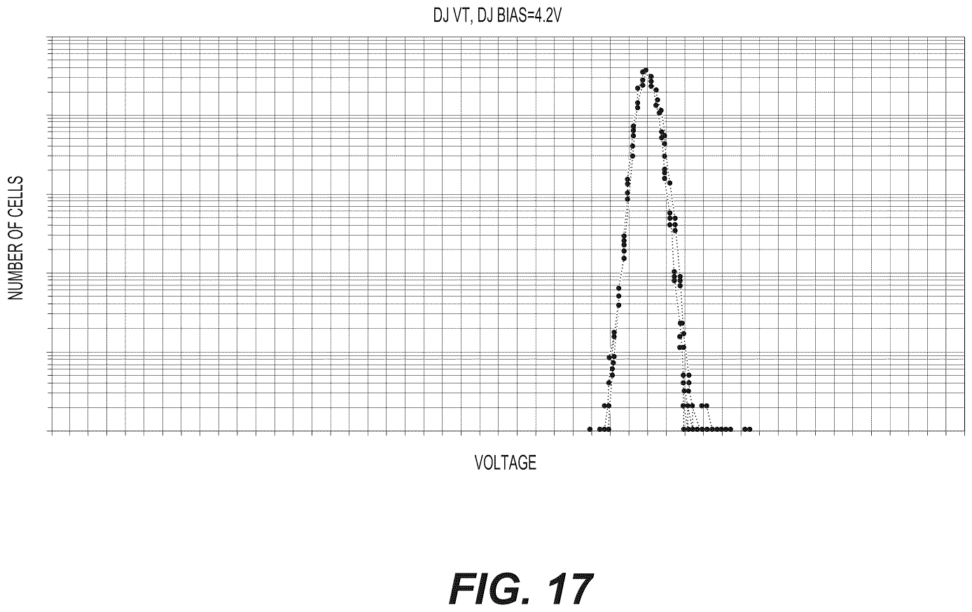

FIG. 15 is a plot of an erase upper tail (Er UT) versus physical word line for the non-ideal threshold voltage of the memory cells connected to the dummy word lines and the tuned threshold voltage of the memory cells connected to the dummy word lines at a high temperature (HT) for the second sub-block SB1. FIG. 16 shows a threshold voltage distribution for the non-ideal threshold voltage of the memory cells connected to the dummy word lines (POR DJ Vt) and the voltage DJ_Bias applied to the dummy word lines during programming of the second sub-block SB1 resulting in corresponding erase upper tail of FIG. 15. FIG. 17 shows a threshold voltage distribution for the tuned threshold voltage (DJ Vt) of the memory cells connected to the dummy word lines and the voltage DJ_Bias applied to the dummy word lines during programming of the second sub-block SB1 resulting in corresponding erase upper tail of FIG. 15. As shown, with even higher threshold voltage of the memory cells connected to the dummy word lines, further erase upper tail improvement is evident for the second sub-block SB1 at high temperature.

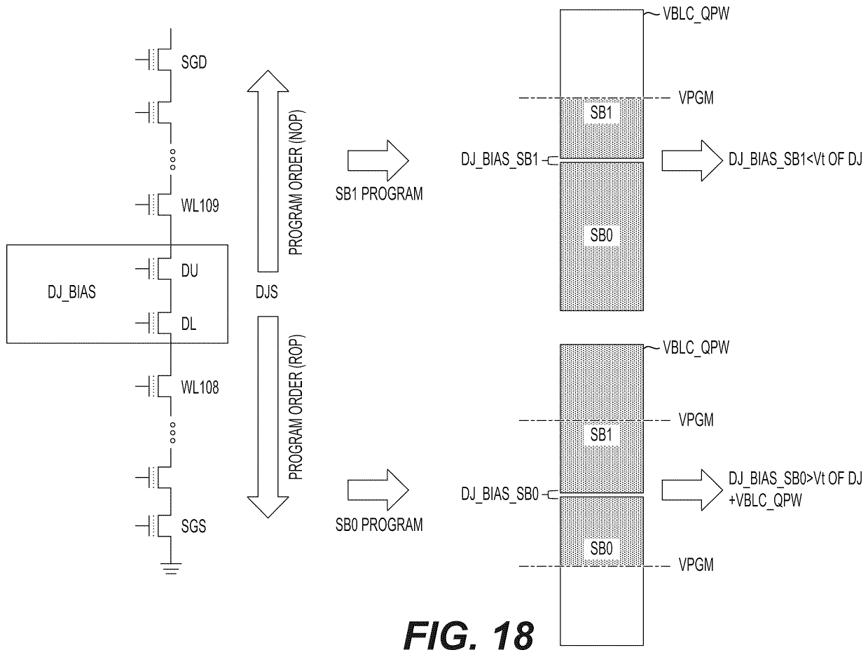

Consequently, described herein is a memory apparatus (e.g., storage system 100 of FIG. 1, memory die 200 of FIG. 2A) including memory cells (e.g., memory cells MC1-MC5 of FIG. 4D) each connected to one of a plurality of word lines (e.g., W of FIG. 3, word line layers WLL91-WLL95 of FIG. 4D) and disposed in memory holes (e.g., memory hole MH of FIG. 3, vertical columns 422, 432, 442, 452, and 453 of FIGS. 4B-4D) extending vertically through a stack (e.g., memory structure 202 of FIG. 3) of the plurality of word lines. The memory cells are configured to retain a threshold voltage corresponding to a plurality of data states (e.g., threshold voltage distributions shown in FIG. 5). The memory cells form a block (e.g., block 0-block M−1 of FIG. 4A) including a first sub-block SB0 (e.g., lower sub-block SB0 of FIG. 4C) vertically below a second sub-block SB1 (e.g., upper sub-block SB1 of FIG. 4C) to define a joint or interface region therebetween (e.g., joint of FIG. 4C). The plurality of word lines include a plurality of dummy word lines (e.g., dummy word lines WLDL, WLDU in FIG. 4C, DU and DL of FIGS. 12 and 14) that are disposed adjacent the interface region. The memory apparatus also includes a control circuit or means (e.g., one or any combination of memory controller 120 of FIG. 1, control circuitry 210, 220, system control logic 260, of FIG. 2A and so forth). The control means is configured to program the memory cells of the first sub-block SB0 and the second sub-block SB1 independently of one another in a program operation. The control means is also configured to apply different bias voltages (e.g., DJ_BIAS of FIGS. 12 and 14) to ones of the plurality of dummy word lines depending on the one of the first sub-block SB0 and the second sub-block SB1 being programmed in the program operation. FIG. 18 shows another block of memory cells divided into a first sub-block SB0 vertically disposed below a second sub-block SB1 along with a corresponding circuit diagram of one memory hole of the block with memory cells connected to dummy word lines at the joint or interface region between the sub-blocks and illustrates voltages (e.g., VBLC_QPW) applied to a bit line connected to each of the memory holes of the block during programming along with a different voltage or bias, DJ_BIAS_SB0 or DJ_BIAS_SB1 applied to the dummy word lines depending on the one of the first sub-block SB0 and the second sub-block SB1 being programmed in the program operation. Thus, the voltage applied to the dummy word lines (DJ bias) for the first sub-block SB0 and second sub-block SB1 during programming DJ_BIAS_SB0, DJ_BIAS_SB1 are separate. Referring back to FIG. 15, it can be seen with such an approach, the second sub-block SB1 erase upper tail for the very last word lines can be improved by more than 100 mV.

As discussed above, each of the memory holes define a channel (e.g., channel 471 of FIG. 4D). According to an aspect, the bias voltages applied to ones of the plurality of dummy word lines during the program operation of the second sub-block SB1 are selected to cut off the channel (i.e., cut off electrically so that there is no current flowing in the channel) to isolate the first sub-block SB0 from the second sub-block SB1. In contrast, the bias voltages applied to the ones of the plurality of dummy word lines during the program operation of the first sub-block SB0 are selected to not cut off the channel.

According to another aspects of the disclosure, the bias voltages DJ_BIAS_SB1 applied to ones of the plurality of dummy word lines during the program operation of the second sub-block SB1 are greater than the bias voltages DJ_BIAS_SB0 applied to the ones of the plurality of dummy word lines during the program operation of the first sub-block SB0. According to other aspects, the bias voltages DJ_BIAS_SB1 applied to ones of the plurality of dummy word lines during the program operation of the second sub-block SB1 are less than the threshold voltage of the memory cells connected to the plurality of dummy word lines.

According to further aspects, the bias voltages DJ_BIAS_SB0 applied to ones of the plurality of dummy word lines during the program operation of the first sub-block SB0 are greater than the threshold voltage of the memory cells connected to the plurality of dummy word lines plus a predetermined amount. As discussed, each of the memory holes is coupled to one of a plurality of bit lines. Thus, according to additional aspects, the control means is further configured to apply each of a plurality of program pulses to selected ones of the plurality of word lines during the program operation. Following each of the plurality of program pulses and for each one of the memory cells, the control means is additionally configured to determine whether the threshold voltage of the one of the memory cells detected exceeds a lower verify level and a higher verify level (e.g., Vv1, Vv2, Vv3, etc. of FIG. 5) of one of the plurality of data states targeted while applying one of a steady state voltage (VSS, approximately 0 volts) or a stepped up voltage (VBLC_QPW) or an inhibiting voltage to ones of the plurality of bit lines coupled to the memory cells being programmed. Such an approach is known as a “quick pass write” (QPW) and is discussed in more detail in U.S. Pat. No. 9,013,928, incorporated herein by reference. While applying each of the plurality of program pulses to the selected ones of the plurality of word lines, the control means applies the steady state voltage to the ones of the plurality of bit lines coupled to the memory cells being programmed to allow programming in response to the threshold voltage of the memory cells being less than the lower verify level. While applying each of the plurality of program pulses to the selected ones of the plurality of word lines, the control means applies the stepped up voltage greater than the steady state voltage to the ones of the plurality of bit lines coupled to the memory cells being programmed to slow programming in response to the threshold voltage of the memory cells being greater than the lower verify level and less than the higher verify level. While applying each of the plurality of program pulses to the selected ones of the plurality of word lines, the control means is also configured to apply the inhibiting voltage greater than the stepped up voltage to the ones of the plurality of bit lines coupled to the memory cells being programmed to inhibit programming in response to the threshold voltage of the memory cells being greater than the higher verify level. Thus, according to an aspect, the predetermined amount is approximately equal to the stepped up voltage.

As mentioned above, the plurality of word lines (e.g., W in FIG. 3, WL0-WL95 in FIG. 4C) and a plurality of dielectric layers (e.g., D in FIG. 3) extend horizontally and overlay one another in an alternating fashion in the stack. The memory cells are connected in series between at least one drain-side select gate transistor (e.g., SGD0-SGD2 in FIG. 4C) on a drain-side of each of the memory holes and at least one source-side select gate transistor (e.g., SGS0-SGS2 in FIG. 4C) on a source-side of each of the memory holes. The at least one drain-side select gate transistor of each of the memory holes is coupled to one of a plurality of bit lines (e.g., bit line 414 of FIG. 4C) and the source-side select gate transistor of each of the memory holes is connected to a source line (e.g., source line SL of FIG. 4C). The plurality of dummy word lines includes an upper dummy word line (e.g., dummy word line WLDU of FIG. 4C, dummy word line DU of FIGS. 12, 14, and 18) and a lower dummy word line (e.g., dummy word line WLDL of FIG. 4C, dummy word line DL of FIGS. 12, 14, and 18) disposed vertically below the upper dummy word line. So, according to an aspect, the control means is further configured to program the memory cells connected to selected ones of the plurality of word lines of the second sub-block SB1 beginning with ones of the plurality of word lines adjacent the upper dummy word line and progressing vertically upward in a normal order program (NOP) during the program operation of the second sub-block SB1. The control means is also configured to program the memory cells connected to the selected ones of the plurality of word lines of the first sub-block SB0 beginning with ones of the plurality of word lines adjacent the lower dummy word line and progressing vertically downward in a reverse order program (ROP) during the program operation of the first sub-block SB0.

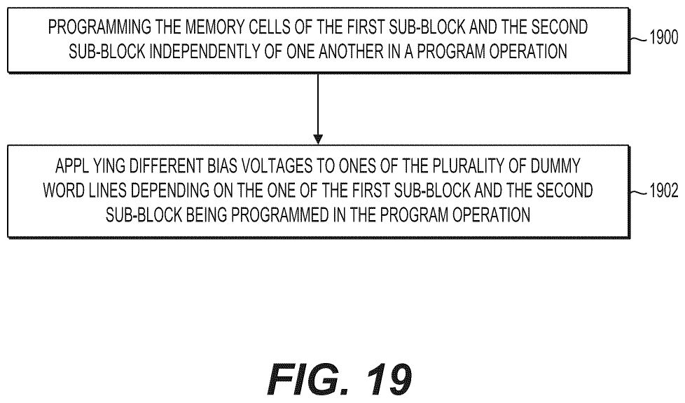

FIG. 19 illustrates steps of a method of operating a memory apparatus. As discussed above, the memory apparatus (e.g., storage system 100 of FIG. 1, memory die 200 of FIG. 2A) includes memory cells (e.g., memory cells MC1-MC5 of FIG. 4D) each connected to one of a plurality of word lines (e.g., W of FIG. 3, word line layers WLL91-WLL95 of FIG. 4D) and disposed in memory holes (e.g., memory hole MH of FIG. 3, vertical columns 422, 432, 442, 452, and 453 of FIGS. 4B-4D) extending vertically through a stack (e.g., memory structure 202 of FIG. 3) of the plurality of word lines. The memory cells are configured to retain a threshold voltage corresponding to a plurality of data states (e.g., threshold voltage distributions shown in FIG. 5). The memory cells form a block (e.g., block 0-block M-1 of FIG. 4A) including a first sub-block SB0 (e.g., lower sub-block SB0 of FIG. 4C) vertically below a second sub-block SB1 (e.g., upper sub-block SB1 of FIG. 4C) to define a joint or interface region therebetween (e.g., joint of FIG. 4C). The plurality of word lines include a plurality of dummy word lines (e.g., dummy word lines WLDL, WLDU in FIG. 4C, DU and DL of FIGS. 12 and 14) that are disposed adjacent the interface region. The method includes the step of 1900 programming the memory cells of the first sub-block SB0 and the second sub-block SB1 independently of one another in a program operation. The method also includes the step of 1902 applying different bias voltages to ones of the plurality of dummy word lines depending on the one of the first sub-block SB0 and the second sub-block SB1 being programmed in the program operation.

Again, as above, each of the memory holes define a channel (e.g., channel 471 of FIG. 4D). According to an aspect, the bias voltages applied to ones of the plurality of dummy word lines during the program operation of the second sub-block SB1 are selected to cut off the channel (i.e., cut off electrically so that there is no current flowing in the channel) to isolate the first sub-block SB0 from the second sub-block SB1. The bias voltages applied to the ones of the plurality of dummy word lines during the program operation of the first sub-block SB0 are selected to not cut off the channel.

As discussed and according to another aspects of the disclosure, the bias voltages DJ_BIAS_SB1 applied to ones of the plurality of dummy word lines during the program operation of the second sub-block SB1 are greater than the bias voltages DJ_BIAS_SB0 applied to the ones of the plurality of dummy word lines during the program operation of the first sub-block SB0. According to further aspects, the bias voltages DJ_BIAS_SB1 applied to ones of the plurality of dummy word lines during the program operation of the second sub-block SB1 are less than the threshold voltage of the memory cells connected to the plurality of dummy word lines.

According to other aspects, the bias voltages DJ_BIAS_SB0 applied to ones of the plurality of dummy word lines during the program operation of the first sub-block SB0 are greater than the threshold voltage of the memory cells connected to the plurality of dummy word lines plus a predetermined amount. As mentioned above, each of the memory holes is coupled to one of a plurality of bit lines. Therefore, according to additional aspects, the method further includes the step of applying each of a plurality of program pulses to selected ones of the plurality of word lines during the program operation. The method additionally includes the step of following each of the plurality of program pulses and for each one of the memory cells, determining whether the threshold voltage of the one of the memory cells detected exceeds a lower verify level and a higher verify level (e.g., Vv1, Vv2, Vv3, etc. of FIG. 5) of one of the plurality of data states targeted while applying one of a steady state voltage (VSS, approximately 0 volts) or a stepped up voltage (VBLC_QPW) or an inhibiting voltage to ones of the plurality of bit lines coupled to the memory cells being programmed. In addition, the method includes the step of while applying each of the plurality of program pulses to the selected ones of the plurality of word lines, applying the steady state voltage to the ones of the plurality of bit lines coupled to the memory cells being programmed to allow programming in response to the threshold voltage of the memory cells being less than the lower verify level. Further, the method includes the step of while applying each of the plurality of program pulses to the selected ones of the plurality of word lines, applying the stepped up voltage greater than the steady state voltage to the ones of the plurality of bit lines coupled to the memory cells being programmed to slow programming in response to the threshold voltage of the memory cells being greater than the lower verify level and less than the higher verify level. The method also includes the step of while applying each of the plurality of program pulses to the selected ones of the plurality of word lines, applying the inhibiting voltage greater than the stepped up voltage to the ones of the plurality of bit lines coupled to the memory cells being programmed to inhibit programming in response to the threshold voltage of the memory cells being greater than the higher verify level. Again, according to an aspect, the predetermined amount is approximately equal to the stepped up voltage.

Once again, the plurality of word lines (e.g., W in FIG. 3, WL0-WL95 in FIG. 4C) and a plurality of dielectric layers (e.g., D in FIG. 3) extend horizontally and overlay one another in an alternating fashion in the stack. The memory cells are connected in series between at least one drain-side select gate transistor (e.g., SGD0-SGD2 in FIG. 4C) on a drain-side of each of the memory holes and at least one source-side select gate transistor (e.g., SGS0-SGS2 in FIG. 4C) on a source-side of each of the memory holes. The at least one drain-side select gate transistor of each of the memory holes is coupled to one of a plurality of bit lines (e.g., bit line 414 of FIG. 4C) and the source-side select gate transistor of each of the memory holes is connected to a source line (e.g., source line SL of FIG. 4C). The plurality of dummy word lines includes an upper dummy word line (e.g., dummy word line WLDU of FIG. 4C, dummy word line DU of FIGS. 12, 14, and 18) and a lower dummy word line (e.g., dummy word line WLDL of FIG. 4C, dummy word line DL of FIGS. 12, 14, and 18) disposed vertically below the upper dummy word line. Thus, according to an aspect, the method further includes the step of programming the memory cells connected to selected ones of the plurality of word lines of the second sub-block SB1 beginning with ones of the plurality of word lines adjacent the upper dummy word line and progressing vertically upward in a normal order program (NOP) during the program operation of the second sub-block SB1. The method also includes the step of programming the memory cells connected to the selected ones of the plurality of word lines of the first sub-block SB0 beginning with ones of the plurality of word lines adjacent the lower dummy word line and progressing vertically downward in a reverse order program (ROP) during the program operation of the first sub-block SB0.

The foregoing detailed description of the invention has been presented for purposes of illustration and description. It is not intended to be exhaustive or to limit the invention to the precise form disclosed. Many modifications and variations are possible in light of the above teachings. The described embodiments were chosen in order to best explain the principles of the invention and its practical application, to thereby enable others skilled in the art to best utilize the invention in various embodiments and with various modifications as are suited to the particular use contemplated. It is intended that the scope of the invention be defined by the claims appended hereto.

What is claimed is:

1. A memory apparatus, comprising:
memory cells each connected to one of a plurality of word lines and disposed in memory holes extending vertically through a stack of the plurality of word lines, the memory cells configured to retain a threshold voltage corresponding to one of a plurality of data states, the memory cells form a block including a first sub-block vertically below a second sub-block to define an interface region therebetween, the plurality of word lines including a plurality of dummy word lines being disposed adjacent the interface region; and
a control means configured to:
program the memory cells of the first sub-block and the second sub-block independently of one another in a program operation, and
apply different bias voltages to ones of the plurality of dummy word lines depending on the one of the first sub-block and the second sub-block being programmed in the program operation.

2. The memory apparatus as set forth in claim 1, wherein each of the memory holes define a channel and the bias voltages applied to ones of the plurality of dummy word lines during the program operation of the second sub-block are selected to cut off the channel to isolate the first sub-block from the second sub-block and the bias voltages applied to the ones of the plurality of dummy word lines during the program operation of the first sub-block are selected to not cut off the channel.

3. The memory apparatus as set forth in claim 1, wherein the bias voltages applied to ones of the plurality of dummy word lines during the program operation of the second sub-block are greater than the bias voltages applied to the ones of the plurality of dummy word lines during the program operation of the first sub-block.

4. The memory apparatus as set forth in claim 1, wherein the bias voltages applied to ones of the plurality of dummy word lines during the program operation of the second sub-block are less than the threshold voltage of the memory cells connected to the plurality of dummy word lines.

5. The memory apparatus as set forth in claim 1, wherein the bias voltages applied to ones of the plurality of dummy word lines during the program operation of the first sub-block are greater than the threshold voltage of the memory cells connected to the plurality of dummy word lines plus a predetermined amount.

6. The memory apparatus as set forth in claim 5, wherein each of the memory holes being coupled to one of a plurality of bit lines and the control means is further configured to:
apply each of a plurality of program pulses to selected ones of the plurality of word lines during the program operation,
following each of the plurality of program pulses and for each one of the memory cells, determine whether the threshold voltage of the one of the memory cells detected exceeds a lower verify level and a higher verify level of one of the plurality of data states targeted while applying one of a steady state voltage or a stepped up voltage or an inhibiting voltage to ones of the plurality of bit lines coupled to the memory cells being programmed,
while applying each of the plurality of program pulses to the selected ones of the plurality of word lines, apply the steady state voltage to the ones of the plurality of bit lines coupled to the memory cells being programmed to allow programming in response to the threshold voltage of the memory cells being less than the lower verify level,
while applying each of the plurality of program pulses to the selected ones of the plurality of word lines, apply the stepped up voltage greater than the steady state voltage to the ones of the plurality of bit lines coupled to the memory cells being programmed to slow programming in response to the threshold voltage of the memory cells being greater than the lower verify level and less than the higher verify level, and
while applying each of the plurality of program pulses to the selected ones of the plurality of word lines, apply the inhibiting voltage greater than the stepped up voltage to the ones of the plurality of bit lines coupled to the memory cells being programmed to inhibit programming in response to the threshold voltage of the memory cells being greater than the higher verify level; and
wherein the predetermined amount is approximately equal to the stepped up voltage.

7. The memory apparatus as set forth in claim 1, wherein the plurality of word lines and a plurality of dielectric layers extend horizontally and overlay one another in an alternating fashion in the stack, the memory cells are connected in series between at least one drain-side select gate transistor on a drain-side of each of the memory holes and at least one source-side select gate transistor on a source-side of each of the memory holes, the at least one drain-side select gate transistor of each of the memory holes is coupled to one of a plurality of bit lines and the source-side select gate transistor of each of the memory holes is connected to a source line, the plurality of dummy word lines includes an upper dummy word line and a lower dummy word line disposed vertically below the upper dummy word line, and the control means is further configured to:
program the memory cells connected to selected ones of the plurality of word lines of the second sub-block beginning with ones of the plurality of word lines adjacent the upper dummy word line and progressing vertically upward in a normal order program during the program operation of the second sub-block; and
program the memory cells connected to the selected ones of the plurality of word lines of the first sub-block beginning with ones of the plurality of word lines adjacent the lower dummy word line and progressing vertically downward in a reverse order program during the program operation of the first sub-block.

8. A controller in communication with a memory apparatus including memory cells each connected to one of a plurality of word lines and disposed in memory holes extending vertically through a stack of the plurality of word lines, the memory cells configured to retain a threshold voltage corresponding to one of a plurality of data states, the memory cells form a block including a first sub-block vertically below a second sub-block to define an interface region therebetween, the plurality of word lines including a plurality of dummy word lines being disposed adjacent the interface region, the controller configured to:
instruct the memory apparatus to program the memory cells of the first sub-block and the second sub-block independently of one another in a program operation; and
instruct the memory apparatus to apply different bias voltages to ones of the plurality of dummy word lines depending on the one of the first sub-block and the second sub-block being programmed in the program operation.

9. The controller as set forth in claim 8, wherein each of the memory holes define a channel and the bias voltages applied to ones of the plurality of dummy word lines during the program operation of the second sub-block are selected to cut off the channel to isolate the first sub-block from the second sub-block and the bias voltages applied to the ones of the plurality of dummy word lines during the program operation of the first sub-block are selected to not cut off the channel.

10. The controller as set forth in claim 8, wherein the bias voltages applied to ones of the plurality of dummy word lines during the program operation of the second sub-block are greater than the bias voltages applied to the ones of the plurality of dummy word lines during the program operation of the first sub-block.

11. The controller as set forth in claim 8, wherein the bias voltages applied to ones of the plurality of dummy word lines during the program operation of the second sub-block are less than the threshold voltage of the memory cells connected to the plurality of dummy word lines.

12. The controller as set forth in claim 8, wherein the bias voltages applied to ones of the plurality of dummy word lines during the program operation of the first sub-block are greater than the threshold voltage of the memory cells connected to the plurality of dummy word lines plus a predetermined amount.

13. The controller as set forth in claim 12, wherein each of the memory holes being coupled to one of a plurality of bit lines and the controller is further configured to:
instruct the memory apparatus to apply each of a plurality of program pulses to selected ones of the plurality of word lines during the program operation,
following each of the plurality of program pulses and for each one of the memory cells, instruct the memory apparatus to determine whether the threshold voltage of the one of the memory cells detected exceeds a lower verify level and a higher verify level of one of the plurality of data states targeted while applying one of a steady state voltage or a stepped up voltage or an inhibiting voltage to ones of the plurality of bit lines coupled to the memory cells being programmed,
instruct the memory apparatus while applying each of the plurality of program pulses to the selected ones of the plurality of word lines, to apply the steady state voltage to the ones of the plurality of bit lines coupled to the memory cells being programmed to allow programming in response to the threshold voltage of the memory cells being less than the lower verify level,
instruct the memory apparatus while applying each of the plurality of program pulses to the selected ones of the plurality of word lines, to apply the stepped up voltage greater than the steady state voltage to the ones of the plurality of bit lines coupled to the memory cells being programmed to slow programming in response to the threshold voltage of the memory cells being greater than the lower verify level and less than the higher verify level, and
instruct the memory apparatus while applying each of the plurality of program pulses to the selected ones of the plurality of word lines, to apply the inhibiting voltage greater than the stepped up voltage to the ones of the plurality of bit lines coupled to the memory cells being programmed to inhibit programming in response to the threshold voltage of the memory cells being greater than the higher verify level; and
wherein the predetermined amount is approximately equal to the stepped up voltage.

14. A method of operating a memory apparatus including memory cells each connected to one of a plurality of word lines and disposed in memory holes extending vertically through a stack of the plurality of word lines, the memory cells configured to retain a threshold voltage corresponding to one of a plurality of data states, the memory cells form a block including a first sub-block vertically below a second sub-block to define an interface region therebetween, the plurality of word lines including a plurality of dummy word lines being disposed adjacent the interface region, the method comprising the steps of:
programming the memory cells of the first sub-block and the second sub-block independently of one another in a program operation; and
applying different bias voltages to ones of the plurality of dummy word lines depending on the one of the first sub-block and the second sub-block being programmed in the program operation.

15. The method as set forth in claim 14, wherein each of the memory holes define a channel and the bias voltages applied to ones of the plurality of dummy word lines during the program operation of the second sub-block are selected to cut off the channel to isolate the first sub-block from the second sub-block and the bias voltages applied to the ones of the plurality of dummy word lines during the program operation of the first sub-block are selected to not cut off the channel.

16. The method as set forth in claim 14, wherein the bias voltages applied to ones of the plurality of dummy word lines during the program operation of the second sub-block are greater than the bias voltages applied to the ones of the plurality of dummy word lines during the program operation of the first sub-block.

17. The method as set forth in claim 14, wherein the bias voltages applied to ones of the plurality of dummy word lines during the program operation of the second sub-block are less than the threshold voltage of the memory cells connected to the plurality of dummy word lines.

18. The method as set forth in claim 14, wherein the bias voltages applied to ones of the plurality of dummy word lines during the program operation of the first sub-block are greater than the threshold voltage of the memory cells connected to the plurality of dummy word lines plus a predetermined amount.

19. The method as set forth in claim 18, wherein each of the memory holes being coupled to one of a plurality of bit lines, the method further including the steps of:
applying each of a plurality of program pulses to selected ones of the plurality of word lines during the program operation,
following each of the plurality of program pulses and for each one of the memory cells, determining whether the threshold voltage of the one of the memory cells detected exceeds a lower verify level and a higher verify level of one of the plurality of data states targeted while applying one of a steady state voltage or a stepped up voltage or an inhibiting voltage to ones of the plurality of bit lines coupled to the memory cells being programmed,
while applying each of the plurality of program pulses to the selected ones of the plurality of word lines, applying the steady state voltage to the ones of the plurality of bit lines coupled to the memory cells being programmed to allow programming in response to the threshold voltage of the memory cells being less than the lower verify level,
while applying each of the plurality of program pulses to the selected ones of the plurality of word lines, applying the stepped up voltage greater than the steady state voltage to the ones of the plurality of bit lines coupled to the memory cells being programmed to slow programming in response to the threshold voltage of the memory cells being greater than the lower verify level and less than the higher verify level, and
while applying each of the plurality of program pulses to the selected ones of the plurality of word lines, applying the inhibiting voltage greater than the stepped up voltage to the ones of the plurality of bit lines coupled to the memory cells being programmed to inhibit programming in response to the threshold voltage of the memory cells being greater than the higher verify level; and
wherein the predetermined amount is approximately equal to the stepped up voltage.

20. The method as set forth in claim 14, wherein the plurality of word lines and a plurality of dielectric layers extend horizontally and overlay one another in an alternating fashion in the stack, the memory cells are connected in series between at least one drain-side select gate transistor on a drain-side of each of the memory holes and at least one source-side select gate transistor on a source-side of each of the memory holes, the at least one drain-side select gate transistor of each of the memory holes is coupled to one of a plurality of bit lines and the source-side select gate transistor of each of the memory holes is connected to a source line, the plurality of dummy word lines includes an upper dummy word line and a lower dummy word line disposed vertically below the upper dummy word line, and the method further includes the steps of:
programming the memory cells connected to selected ones of the plurality of word lines of the second sub-block beginning with ones of the plurality of word lines adjacent the upper dummy word line and progressing vertically upward in a normal order program during the program operation of the second sub-block; and
programming the memory cells connected to the selected ones of the plurality of word lines of the first sub-block beginning with ones of the plurality of word lines adjacent the lower dummy word line and progressing vertically downward in a reverse order program during the program operation of the first sub-block.
